(19) United States
(12) Patent Application Publication
(10) Pub. No.: US 2026/0213504 A1
(43) Pub. Date: Jul. 23, 2026

(54) ELECTRICAL CONNECTION UNIT

(71) Applicant: YAZAKI CORPORATION, Tokyo (JP)

(72) Inventor: Ryu Senoo, Kakegawa-shi (JP)

(21) Appl. No.: 19/430,268

(22) Filed: Dec. 23, 2025

(30) Foreign Application Priority Data
Jan. 23, 2025 (JP) 2025-009676

(51) Int. Cl. H02B 1/56; H05K 7/20

(52) U.S. Cl. CPC H02B 1/56; H05K 7/20409; H05K 7/20436; H05K 7/20509; H05K 7/20518

(57) ABSTRACT

An electrical connection unit includes a heat dissipation member, a first electronic component, a first heat transfer member, a second electronic component, and a second heat transfer member. The first electronic component is disposed on a first side of the heat dissipation member. The first heat transfer member is disposed on a first side of the first electronic component and is configured to be disposed between the first electronic component and an external cooler. The second electronic component is disposed on a second side of the heat dissipation member. The second heat transfer member is disposed between the second electronic component and the heat dissipation member.

### BACKGROUND OF THE INVENTION

### Field of the Invention

Embodiments of the present invention relate to an electrical connection unit.

Priority is claimed on Japanese Patent Application No. 2025-9676 filed in Japan on Jan. 23, 2025, the content of which is incorporated herein by reference.

### Description of Related Art

It is known that electronic components such as a relay and a resistor are mounted on a mounting surface of a housing in an electrical connection unit.

### PRIOR ART DOCUMENT

### Patent Document

Patent Document 1: Japanese Unexamined Patent Application, First Publication No. 2018-113184

### SUMMARY OF THE INVENTION

Incidentally, the electrical connection unit is expected to have improved thermal characteristics.

An embodiment provides an electrical connection unit capable of improving thermal characteristics.

An electrical connection unit according to an embodiment includes a heat dissipation member, a first electronic component, a first heat transfer member, a second electronic component, and a second heat transfer member. The first electronic component is disposed on a first side of the heat dissipation member. The first heat transfer member is disposed on a first side of the first electronic component and is configured to be disposed between the first electronic component and an external cooler. The second electronic component is disposed on a second side of the heat dissipation member. The second heat transfer member is disposed between the second electronic component and the heat dissipation member.

According to an embodiment, the thermal characteristics of the electrical connection unit can be improved.

### BRIEF DESCRIPTION OF THE DRAWINGS

FIG. 1 is a perspective view illustrating an electrical connection unit according to an embodiment.

FIG. 2 is a partially exploded perspective view illustrating the electrical connection unit according to the embodiment.

FIG. 3 is another partially exploded perspective view illustrating the electrical connection unit according to the embodiment.

FIG. 4 is a perspective view for describing an electronic component and a connection component according to the embodiment.

FIG. 5 is a partially exploded perspective view illustrating a first structure according to the embodiment.

FIG. 6 is a perspective view illustrating one of routing boards according to the embodiment.

FIG. 7 is a plan view illustrating one of the routing boards according to the embodiment.

FIG. 8 is a cross-sectional view of a structure taken along line F8-F8 in FIG. 7.

FIG. 9 is a cross-sectional view additionally illustrating a partial constitution of the electrical connection unit in FIG. 8.

FIG. 10 is a partially exploded perspective view illustrating a second structure according to the embodiment.

FIG. 11 is an exploded perspective view illustrating the first structure and a heat dissipation member according to the embodiment.

### DETAILED DESCRIPTION OF THE INVENTION

Hereinafter, embodiments will be described with reference to the drawings. In the following description, constitutions having the same or similar functions are denoted by the same reference numbers. Redundant descriptions of these constitutions may be omitted. Note that the constitution described below does not limit the scope of the embodiment.

In the present disclosure, the terms are defined as follows. The term “connection” is not limited to a mechanical connection, and may include an electrical connection. That is, the term “connection” is not limited to a case where two elements that are connection targets are directly connected, and may include a case where two elements that are connection targets are connected with another element interposed therebetween. The term “accommodation” is not limited to a case where the entire component is accommodated, and may include a case where only a part of the component is accommodated (a state in which the remaining part of the component protrudes). The terms “facing” and “overlapping” indicate that virtual projection images of two target objects overlap each other when viewed from a specific direction. That is, the terms “facing” and “overlapping” are not limited to a case where two target objects directly face each other, and may include a case where two target objects face each other in a state in which another member exists between the two target objects. “Parallel”, “orthogonal”, or “the same” may include “substantially parallel”, “substantially orthogonal”, or “substantially the same”, respectively. “Covering” may include “covering a major portion while exposing a portion”.

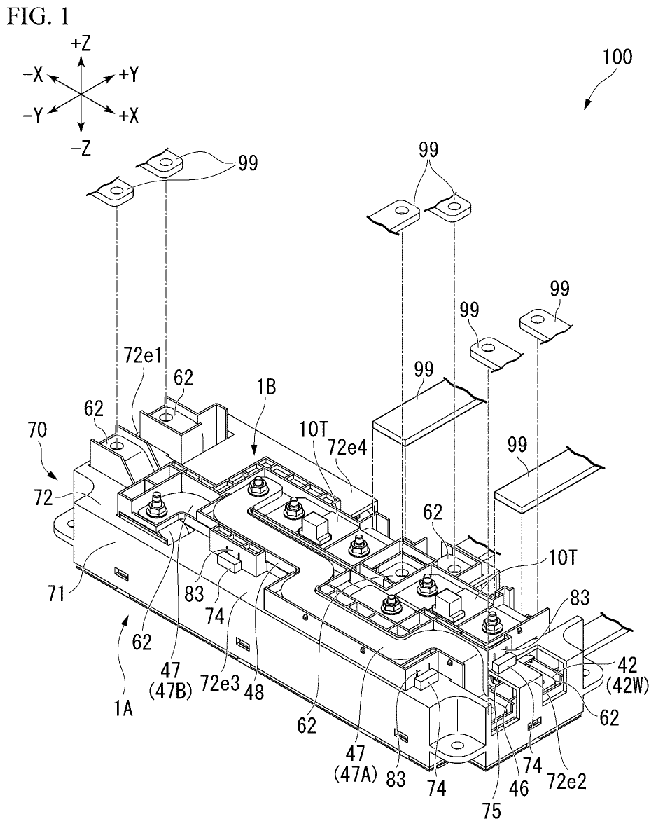

In the present disclosure, a +X direction, a −X direction, a +Y direction, a −Y direction, a +Z direction, and a −Z direction are defined as follows. The +X direction is a direction from a first end 72e1 to a second end 72e2 of a metal cover 70 described below (see FIG. 1). The −X direction is a direction opposite to the +X direction. Hereinafter, the +X direction and the −X direction are simply referred to as an “X direction” when they are not distinguished from each other. The +Y direction and the −Y direction are directions intersecting (for example, orthogonal to) the X direction. The +Y direction is a direction from a third end 72e3 to a fourth end 72e4 of the metal cover 70 described below (see FIG. 1). The −Y direction is a direction opposite to the +Y direction. Hereinafter, the +Y direction and the −Y direction are simply referred to as a “Y direction” when they are not distinguished from each other. The +Z direction and the −Z direction are directions intersecting (for example, orthogonal to) the X direction and the Y direction. The +Z direction is a plate thickness direction of a ceiling wall portion 72 included in the metal cover 70 (see FIG. 1). The −Z direction is a direction opposite to the +Z direction. Hereinafter, the +Z direction and the −Z direction are simply referred to as “Z direction” when they are not distinguished from each other. The Z direction is an example of a “first direction”. The X direction is an example of a “second direction”. The Y direction is an example of a “third direction”. The “second direction” is not limited to the X direction, and may be the Y direction or other directions. The “third direction” is not limited to the Y direction, and is a direction intersecting the “first direction” and the “second direction”.

Hereinafter, the X direction and the Y direction may be referred to as a “horizontal direction” when they are not distinguished from each other. Hereinafter, the Z direction may be referred to as a “vertical direction”. Hereinafter, a +Z direction side may be referred to as an “upper” side, and a −Z direction side may be referred to as a “lower” side. However, these expressions are expressions for convenience of description, and do not limit a gravity direction of an electrical connection unit 100 (an installation posture of the electrical connection unit 100).

### Embodiment

### <1. Constitution of Electrical Connection Unit>

The electrical connection unit 100 is, for example, in-vehicle equipment mounted on a vehicle such as an electric vehicle (EV), a hybrid electric vehicle (HEV), or a plug-in hybrid electric vehicle (PHEV). The electrical connection unit 100 may be referred to as an “electrical connection box” or a “junction box”, for example. However, the electrical connection unit 100 is not limited to a box-shaped device.

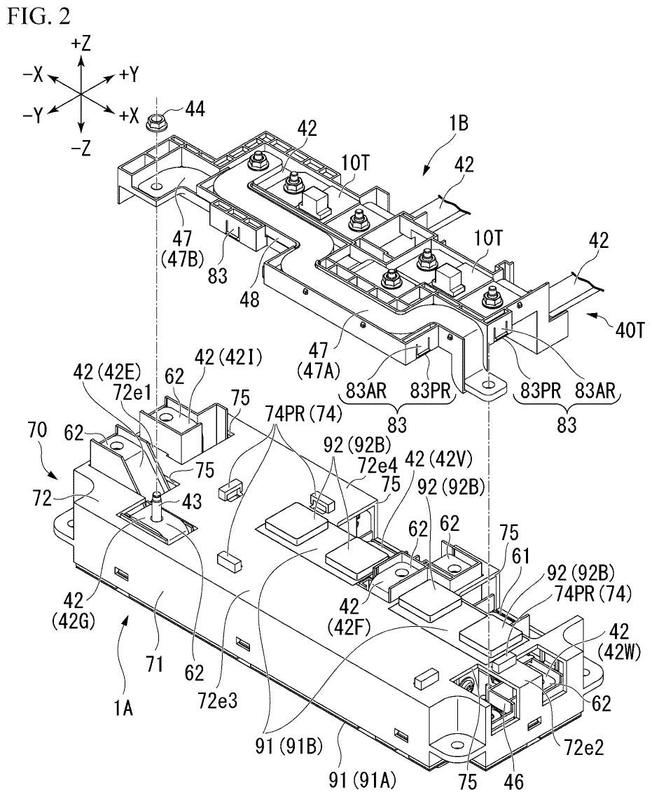

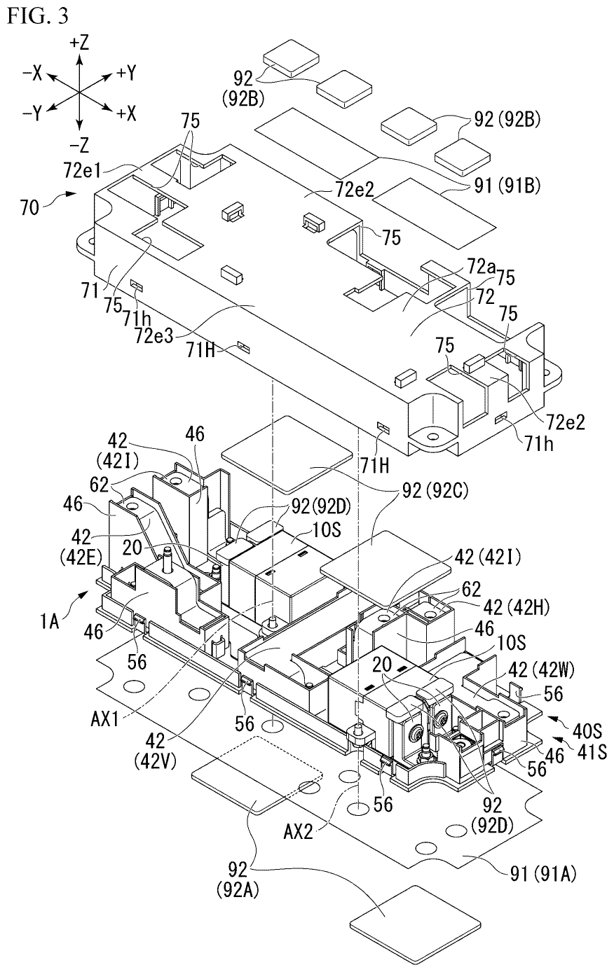

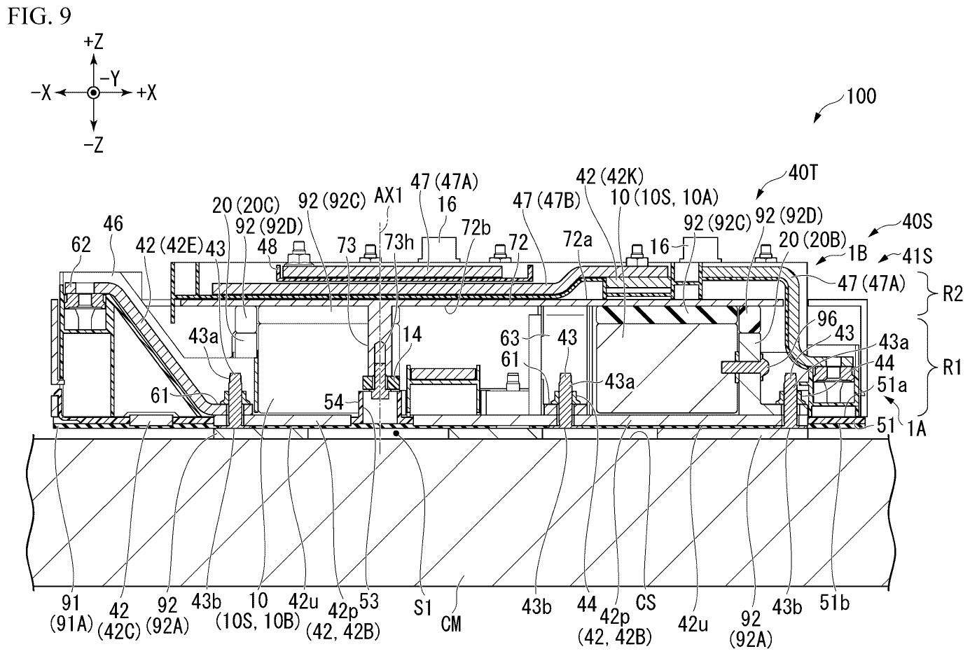

As illustrated in FIGS. 1 to 3, the electrical connection unit 100 includes, for example, a first structure 1A, a second structure 1B, a plurality of connection bus bars 47 (see FIG. 2), a second auxiliary member 48 (see FIG. 2), the metal cover 70, an insulating sheet 91 (see FIG. 3), and a heat transfer member 92 (see FIG. 3). The electrical connection unit 100 is disposed in a state of being in contact with an external cooler CM (see FIG. 9). The external cooler CM is, for example, a water jacket. The external cooler CM receives heat from the electrical connection unit 100 via a cooling surface CS of the cooler CM (see FIG. 9), and cools the electrical connection unit 100. The electrical connection unit 100 may further include a cover that covers the second structure 1B from the +Z direction as necessary.

The first structure 1A is a unit forming a first-level portion of a two-level hierarchical structure of the electrical connection unit 100. The second structure 1B is a unit forming a second-level portion of the two-level hierarchical structure of the electrical connection unit 100.

In the present embodiment, the electrical connection unit 100 includes a first region (first space) R1 and a second region (second space) R2 (see FIG. 9). The first region R1 is, for example, a region in which a heat dissipation property is emphasized. In the first region R1, for example, an electronic component 10S having a greater amount of heat generation than an electronic component 10T described below is disposed. On the other hand, the second region R2 is a region in which a characteristic (for example, improvement in operation stability of an electronic component 10 to be mounted, ease of component replacement, routing, or degree of freedom in design) different from the heat dissipation property is emphasized. In the second region R2, for example, the electronic component 10T having a smaller amount of heat generation than the electronic component 10S described below is disposed. However, these contents do not limit contents of the electrical connection unit 100 of the present disclosure. For example, the amount of heat generation of the electronic component 10T may be greater than the amount of heat generation of the electronic component 10S. Hereinafter, the electronic component 10S and the electronic component 10T are referred to as the “electronic component 10” when they are not distinguished from each other.

### <1.1 Constitution of First Structure>

As illustrated in FIG. 3, the first structure 1A in the present embodiment is a unit in which the heat dissipation property is emphasized. The first structure 1A includes a plurality of electronic components 10S, a plurality of connection components 20, and a routing board 40S. The plurality of electronic components 10S are electrically connected to the routing board 40S. The electronic component 10 (electronic component 10S) included in the first structure 1A is an example of a “first electronic component”.

The first structure 1A is disposed in the first region R1 of the electrical connection unit 100 described above (see FIG. 9). The first structure 1A faces a second surface 72b of the metal cover 70 described below in the Z direction (for example, the first structure 1A faces the metal cover 70 from the −Z direction) (see FIG. 9). The first structure 1A faces the cooler CM in the Z direction. The plurality of electronic components 10S included in the first structure 1A are disposed on a second side (for example, the +Z direction side) of a base member 41S (described below).

In the present disclosure, a first side and the second side are defined as follows.

In a case where the plate thickness direction of the ceiling wall portion 72 included in the metal cover 70 is the first direction, the first side is one side (for example, the −Z direction side) in the first direction, and the second side is the other side (for example, the +Z direction side) in the first direction.

### <1.2 Constitution of Second Structure>

As also illustrated in FIG. 2, the second structure 1B in the present embodiment is a unit in which a characteristic different from the heat dissipation property is emphasized. The second structure 1B includes a plurality of electronic components 10T, a plurality of bus bars 42, and a cover member 40T. The electronic component 10T is electrically connected to the bus bar 42 (described below). The electronic component 10 (electronic component 10T) included in the second structure 1B is an example of a “second electronic component”.

The second structure 1B is disposed in the second region R2 of the electrical connection unit 100 described above (see FIG. 9). For example, the second structure 1B is disposed on a side opposite to the first structure 1A with respect to the ceiling wall portion 72 (described below) of the metal cover 70 (see FIG. 9). The second structure 1B faces a first surface 72a of the metal cover 70 described below in the Z direction (for example, the second structure 1B faces the metal cover 70 from the +Z direction side) (see FIG. 9). The plurality of electronic components 10T included in the second structure 1B are disposed on the second side (for example, the +Z direction side) of the cover member 40T (described below).

The first structure 1A may be constituted by a plurality of units individually formed according to application functions in the first structure 1A. The second structure 1B may be constituted by a plurality of units individually formed according to application functions in the second structure 1B.

### 2. Detailed Constitution of First Structure

Next, the constitution of the first structure 1A included in the electrical connection unit 100 will be described in detail.

### <2.1 Electronic Component 10S>

In the present embodiment, the plurality of electronic components 10 included in the electrical connection unit 100 include the electronic component 10S. For example, the electronic component 10S is an electronic component whose amount of heat generation during energization is greater than that of the electronic component 10T. The electronic component 10S is a relay (for example, a mechanical relay or a semiconductor relay), a pyrofuse, or the like. However, the type of the electronic component 10S is not limited to the above example.

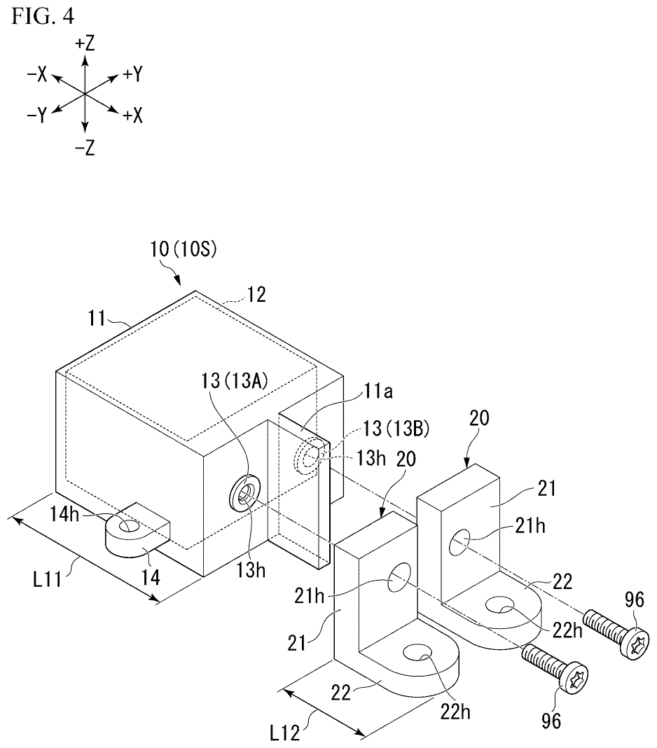

FIG. 4 is a perspective view illustrating the electronic component 10S and the connection component 20. The electronic component 10S is, for example, an electronic component in which a plurality of terminals 13 are disposed to be arranged at one end of the electronic component 10S. The electronic component 10S includes, for example, a case 11, a component body 12, the plurality of terminals 13, and a plurality of attachment portions 14.

### Case

The case 11 is an outer member that forms most of an outer shape of the electronic component 10S. The case 11 is made of, for example, a synthetic resin and has an insulating property. The case 11 accommodates the component body 12. The case 11 and the component body 12 may be integrally formed.

In the present embodiment, the case 11 has an insulating rib 11a that protrudes in the horizontal direction (for example, the X direction) and extends in the Z direction. The insulating rib 11a has, for example, a plate shape extending in the horizontal direction (for example, the X direction) and the Z direction. The insulating rib 11a extends over the entire length of the case 11 in the Z direction, for example. The insulating rib 11a is disposed between the plurality of terminals 13 (a terminal 13A and a terminal 13B described below). The insulating rib 11a electrically insulates between the terminal 13A and the terminal 13B. In the present embodiment, a part of the insulating rib 11a is disposed between first portions 21 (described below) of the two connection components 20 connected to the electronic component 10S. The insulating rib 11a electrically insulates between the first portions 21 of the two connection components 20 connected to the electronic component 10S.

### Component Body

The component body 12 is a portion that performs a main function of the electronic component 10S. For example, in a case where the electronic component 10S is a relay, the component body 12 includes a switch (for example, a contact portion) that switches between a conductive state and a non-conductive state. For example, in a case where the electronic component 10S is a fuse, the component body 12 includes a fusion portion that is fused when an overcurrent flows. For example, in a case where the electronic component 10S is a capacitor, the component body 12 includes a portion that accumulates electric charges.

### Terminal

The terminal 13 is an electrical connection portion exposed to the outside of the case 11. The terminal 13 is electrically connected to the component body 12 inside the case 11. In the present embodiment, the electronic component 10S includes the terminal 13A and the terminal 13B as the plurality of terminals 13. One of the terminal 13A and the terminal 13B is a terminal on a positive electrode side. The other of the terminal 13A and the terminal 13B is a terminal on a negative electrode side. In the electronic component 10S, one of the terminal 13A and the terminal 13B is an example of a “first terminal”. The other of the terminal 13A and the terminal 13B is an example of a “second terminal”.

In the electronic component 10S of the present embodiment, the terminal 13A and the terminal 13B are provided at one end of the electronic component 10S in the horizontal direction (for example, the X direction). The terminal 13A and the terminal 13B are disposed to be arranged in the horizontal direction (for example, the Y direction). Each of the terminal 13A and the terminal 13B is directed in the horizontal direction (for example, the X direction). Each terminal 13 has an attachment hole 13h to which a fastening member 96 (for example, a screw or a bolt) described below is attached. The attachment hole 13h is open in the horizontal direction (for example, the Y direction). An inner circumferential surface of the attachment hole 13h of the electronic component 10S has a screw groove.

### Attachment Portion

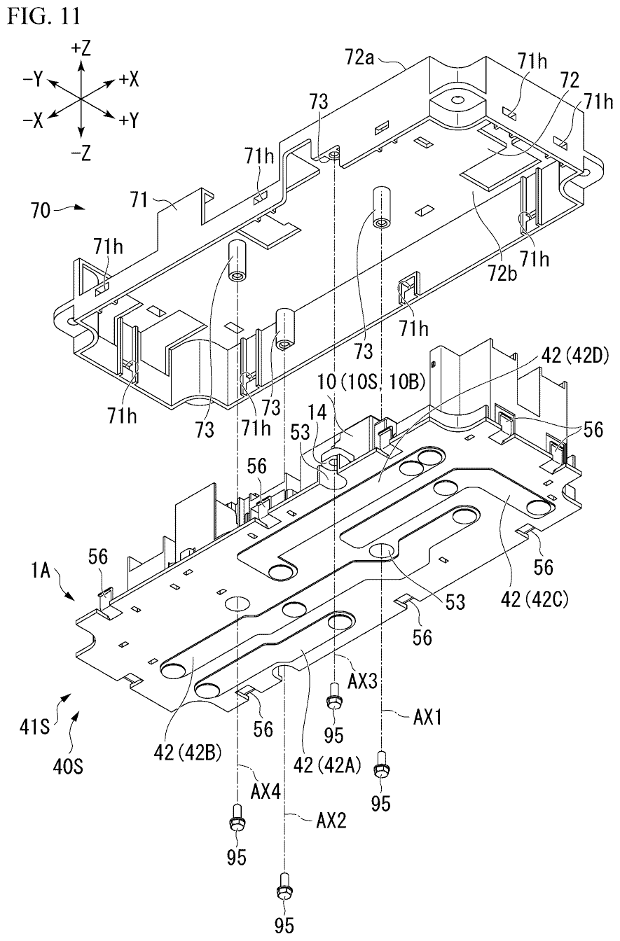

The attachment portion 14 is a portion for fixing the electronic component 10S. The attachment portion 14 has an attachment hole 14h to which a fastening member 95 (for example, a screw or a bolt; and see FIG. 11) described below is attached. The attachment hole 14h is open in the Z direction. The attachment hole 14h is an insertion hole through which the fastening member 95 passes. The attachment hole 14h faces an attachment hole 73h (see FIG. 9) of a fixing portion 73 described below. The attachment hole 14h is an example of a “second attachment hole”.

### <2.2 Connection Component>

Next, the connection component 20 will be described. The connection component 20 is a component that electrically connects the electronic component 10S to the routing board 40S. For example, the connection component 20 electrically connects the electronic component 10 (for example, the electronic component 10S) included in the plurality of electronic components 10 included in the first structure 1A to a bus bar 42 included in the first structure 1A. The connection component 20 forms a part of an energization path in the first structure 1A. The connection component 20 in the present disclosure is a member forming the energization path in the vertical direction. For example, the connection component 20 forms an energization path from the electronic component 10S toward the −Z direction side in the first structure 1A. The connection component 20 is made of metal (for example, copper, a copper alloy, aluminum, or an aluminum alloy). The connection component 20 may also be referred to as a “vertical routing member”. Further, the connection component 20 may also be referred to as a “metal component”.

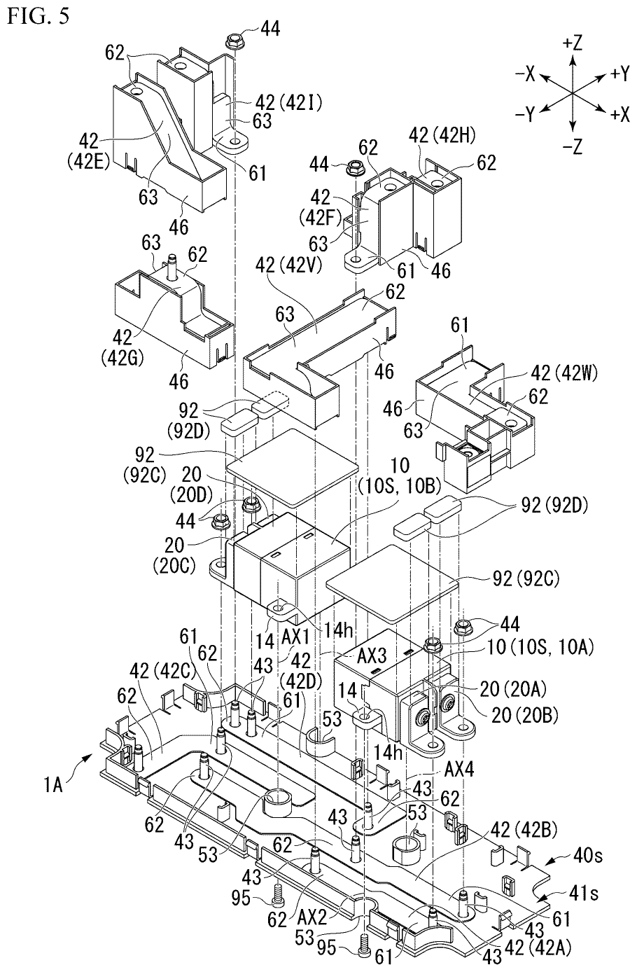

In the present embodiment, the connection component 20 electrically connects the electronic component 10S to the bus bar 42 (see FIG. 5) included in the routing board 40S. In the present embodiment, a length L12 of the connection component 20 in a longitudinal direction (for example, the Y direction) of the electronic component 10S is smaller than a length L11 of the electronic component 10S in the longitudinal direction. The connection component 20 includes, for example, a first portion 21 and a second portion 22.

### First Portion

The first portion 21 of the connection component 20 is a portion connected to the terminal 13 of the electronic component 10S. The first portion 21 is a plate-shaped or rectangular parallelepiped portion extending in the Z direction. The first portion 21 extends in the Z direction along one end (for example, an end in the X direction) of the electronic component 10S. The first portion 21 is a standing portion that stands in the Z direction with respect to the routing board 40S (for example, with respect to the bus bar 42 described below). The first portion 21 is adjacent to the electronic component 10S in the horizontal direction (for example, the X direction). For example, the first portion 21 is adjacent to the terminal 13 of the electronic component 10S in the horizontal direction (for example, the X direction), and is connected to the terminal 13 of the electronic component 10S from the horizontal direction (for example, the X direction).

The first portion 21 of the connection component 20 has an attachment hole 21h through which the fastening member 96 (for example, a screw or a bolt) passes. The attachment hole 21h is open in the horizontal direction (for example, the X direction). The fastening member 96 that has passed through the attachment hole 21h is engaged with the attachment hole 13h of the terminal 13 of the electronic component 10S, and thus, the first portion 21 is physically and electrically connected to the terminal 13 of the electronic component 10S.

### Second Portion

The second portion 22 of the connection component 20 is a portion connected to the bus bar 42 (see FIG. 5). The second portion 22 protrudes in the horizontal direction (for example, the X direction) from an end of the first portion 21 on the −Z direction side. The second portion 22 is a plate portion extending in the horizontal direction. The second portion 22 is adjacent to the bus bar 42 in the Z direction and is connected to the bus bar 42 from the Z direction (see FIG. 5). The second portion 22 of the connection component 20 is attached, from the Z direction, to a fastening member 43 (for example, a screw or bolt; and see FIG. 5) protruding from the bus bar 42 in the +Z direction, and is physically and electrically connected to the bus bar 42. In the present embodiment, the second portion 22 of the connection component 20 has an attachment hole 22h through which the fastening member 43 passes. The attachment hole 22h is open in the Z direction. In the second portion 22, the fastening member 43 passes through the attachment hole 22h. An engagement member 44 (for example, a nut; and see FIGS. 5, 9, and the like) is engaged with a tip of the fastening member 43 that has passed through the attachment hole 22h, so that the second portion 22 is fixed to the bus bar 42. In the present embodiment, the first portion 21 and the second portion 22 form one L-shaped connection component 20.

In the present embodiment, the bus bar 42 is disposed at a position away from the terminal 13 of the electronic component 10S (for example, a position away in the Z direction). The connection component 20 is disposed between the electronic component 10S and the bus bar 42. In the present disclosure, the phrase “the connection component is disposed between the electronic component and the bus bar” is not limited to a case where a part of the connection component is located between the electronic component and the bus bar when viewed from the X direction or the Y direction. The phrase “the connection component is disposed between the electronic component and the bus bar” may correspond to a case where a part of the connection component is located between the electronic component and the bus bar when viewed from a direction inclined with respect to the X direction or the Y direction. The connection component 20 electrically connects the terminal 13 of the electronic component 10S to the bus bar 42.

### <2.3 Constitution of Routing Board of First Structure>

The routing board 40S in the first structure 1A will be described in detail.

FIG. 5 is a perspective view for describing the routing board 40S. The routing board 40S is a member that forms the energization path between the plurality of electronic components 10S included in the first structure 1A. In the present embodiment, the routing board 40S has a plate shape extending in the X direction and the Y direction.

In the present disclosure, the “routing board” indicates a board-type routing board. The “board type” indicates a plate shape extending along one plane when viewed as a whole regardless of a fine shape. In the present disclosure, the term “plate shape”, “sheet shape”, or “planar” is not limited to the case of being completely flat, and may include a case where a fixing structure, a rib, or the like protruding in the Z direction is partially present, a case where an uneven shape following a thickness of the bus bar is present on the surface, and the like.

The routing board 40S includes, for example, the base member 41S, a plurality of bus bars 42, and a plurality of fastening members 43. In the present embodiment, the base member 41S and some bus bars 42 are integrated through insert molding. For example, the routing board 40S is formed as one piece member by insert-molding the bus bar 42 with the base member 41S after the fastening member 43 is fixed to the bus bar 42. That is, some bus bars 42 are integrated with the base member 41S without using a fastening member such as a screw or a bolt. Note that the routing board 40S may be formed by using another structure instead of the insert molding. A modification example in which the routing board 40S is formed by using another structure will be described later.

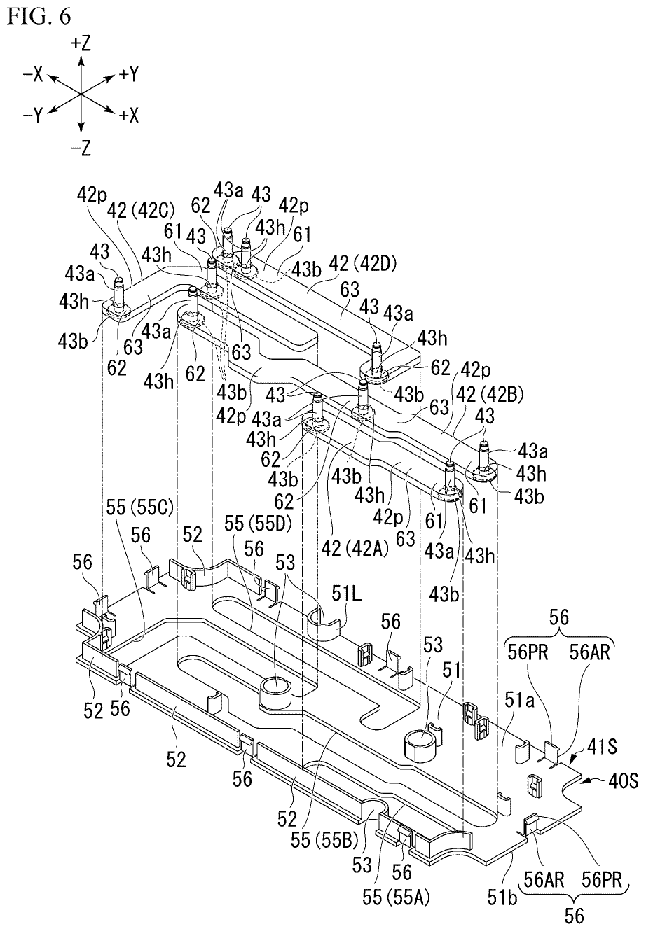

FIG. 6 is a partially exploded perspective view illustrating the routing board 40S. Hereinafter, for convenience of description, the base member 41S, the bus bar 42, and the fastening member 43 will be described with reference to the partially exploded drawing of the routing board 40S.

### <2.3.1 Base Member>

The base member 41S is a support member that supports the plurality of electronic components 10S or/and the plurality of bus bars 42. The base member 41S in the present embodiment supports the bus bar 42 and indirectly supports the plurality of electronic components 10S via the connection components 20. The plurality of bus bars 42 are arranged in the horizontal direction at intervals. The base member 41S electrically insulates between the plurality of bus bars 42. The base member 41S includes, for example, a flat surface portion 51, a wall portion 52, and a plurality of opening portions 53. The base member 41S is made of, for example, a synthetic resin and has an insulating property.

The base member 41S included in the routing board 40S is an example of a “support”. The base member 41S supports the bus bar 42 (for example, bus bars 42A, 42B, 42C, and 42D) electrically connected to the electronic component 10S among the plurality of bus bars 42 included in the routing board 40S. Among the plurality of bus bars 42 included in the routing board 40S, the bus bar 42 electrically connected to the electronic component 10S is an example of a “first routing member”. In the present embodiment, four bus bars 42A, 42B, 42C, and 42D are the “first routing members” (see FIG. 5).

### Flat Surface Portion

The flat surface portion 51 is a portion formed in a plate shape in the base member 41S. The flat surface portion 51 has a plate shape extending in the horizontal direction. The flat surface portion 51 forms a main portion of the base member 41S. The flat surface portion 51 forms a base portion (insulating base portion) of the base member 41S. In the present embodiment, the flat surface portion 51 extends over the entire width of the base member 41S in the X direction and over the entire width of the base member 41S in the Y direction except for the wall portion 52 of the base member 41S.

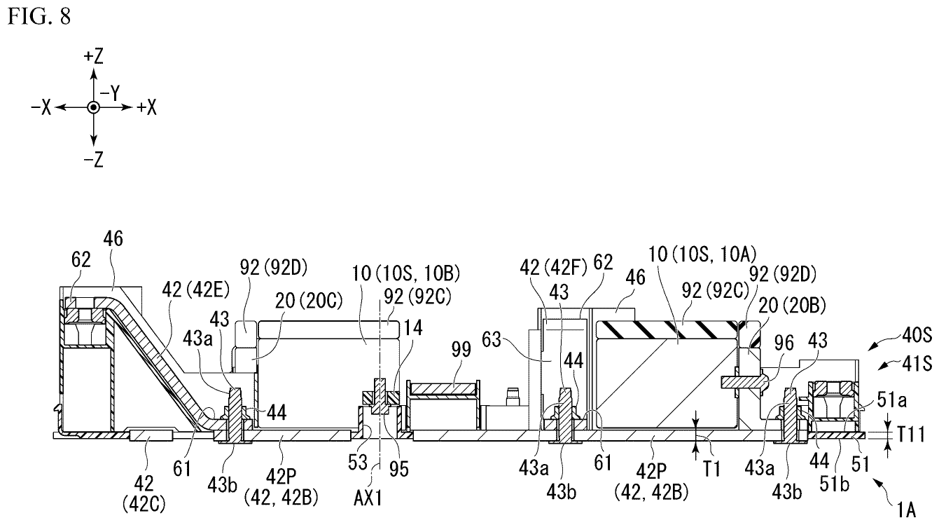

The flat surface portion 51 has a first surface 51a and a second surface 51b. The first surface 51a is a surface directed in the +Z direction. The first surface 51a is a flat surface extending in the horizontal direction. The first surface 51a faces the plurality of electronic components 10S and faces the metal cover 70 (see FIG. 9). The second surface 51b is located on a side opposite to the first surface 51a. The second surface 51b is a surface directed in the −Z direction. The second surface 51b is a flat surface extending in the horizontal direction. The second surface 51b faces the external cooler CM (see FIG. 9). A thickness direction (plate thickness direction) of the flat surface portion 51 is the Z direction, and coincides with an opening direction of the base member 41S in the opening portion 53. In the present embodiment, a thickness T11 of the flat surface portion 51 in the Z direction is smaller than a thickness T1 of the bus bar 42 in the Z direction (for example, a thickness of a horizontal plate portion 42p described below in the Z direction) (see FIG. 8). The thickness T11 of the flat surface portion 51 in the Z direction may be equal to the thickness T1 of the bus bar 42 in the Z direction, or may be larger than the thickness T1 of the bus bar 42 in the Z direction.

The flat surface portion 51 has, for example, one or more accommodation portions 55 in which some bus bars 42 are accommodated. For example, in the present embodiment, the flat surface portion 51 has a plurality of accommodation portions 55. The plurality of accommodation portions 55 are formed apart from each other in the X direction or the Y direction. Each accommodation portion 55 is, for example, a through-hole penetrating through the flat surface portion 51 in the Z direction. The accommodation portion 55 may be a recess provided on the first surface 51a or the second surface 51b of the flat surface portion 51 and recessed in the Z direction, instead of a through-hole. In the present disclosure, the phrase “the accommodation portion penetrates through the flat surface portion in the first direction (Z direction)” may include a case where a part of the entire length of the accommodation portion 55 penetrates through the flat surface portion 51 in the Z direction (for example, the remaining portion of the accommodation portion 55 may be a recess recessed in the Z direction, or may be provided inside the base member 41S and not exposed to the outside of the base member 41S). Similarly, in the present disclosure, the phrase “the accommodation portion is recessed in the first direction (Z direction)” may include a case where a part of the entire length of the accommodation portion 55 is recessed in the Z direction (for example, the remaining portion of the accommodation portion 55 may be a through-hole penetrating through the flat surface portion 51 in the Z direction, or may be provided inside the base member 41S and not exposed to the outside of the base member 41S).

Each accommodation portion 55 has an outer shape corresponding to a shape of the bus bar 42 to be accommodated when viewed from the Z direction. The plurality of accommodation portions 55 include, for example, four accommodation portions 55A, 55B, 55C, and 55D. The accommodation portion 55A is provided to correspond to the bus bar 42A described below, and accommodates at least a part of the bus bar 42A. The accommodation portion 55B is provided to correspond to the bus bar 42B described below, and accommodates at least a part of the bus bar 42B. The accommodation portion 55C is provided to correspond to the bus bar 42C described below, and accommodates at least a part of the bus bar 42C. The accommodation portion 55D is provided to correspond to the bus bar 42D described below, and accommodates at least a part of the bus bar 42D.

The flat surface portion 51 has one or more locking portions 56. The locking portion 56 is used for locking the metal cover 70 and the first structure 1A. An example of the locking portion 56 is a fitting claw (also referred to as a “snap-fit”). The fitting claw includes an arm portion 56AR extending in the +Z direction from the flat surface portion 51 and a protruding portion 56PR protruding as a part of the arm portion 56AR. The protruding portion 56PR protrudes from the arm portion 56AR in a direction intersecting an extending direction (+Z direction) of the arm portion 56AR. In the present embodiment, the protruding portion 56PR protrudes toward the metal cover 70 and is locked to a holding portion 71h described below (see FIG. 1). For example, the protruding portion 56PR has an inclined surface inclined with respect to the Z direction. In work of attaching the first structure 1A to the metal cover 70, when the locking portion 56 approaches the metal cover 70, the protruding portion 56PR is pressed by a peripheral wall 71 (described below) of the metal cover 70, and the arm portion 56AR is thus elastically deformed in a predetermined direction. Then, once the protruding portion 56PR reaches the holding portion 71h, the arm portion 56AR is recovered from the deformed state, whereby the protruding portion 56PR is locked to the holding portion 71h.

### Wall Portion

The wall portion 52 is provided at a peripheral end of the base member 41S. The wall portion 52 is a reinforcement rib protruding in the +Z direction from an end of the flat surface portion 51. The wall portion 52 may be used for positioning the first structure 1A and the metal cover 70 at the time of assembly. Note that the wall portion 52 may be omitted.

### Opening Portion

The opening portion 53 is an opening facing the attachment hole 73h of the fixing portion 73 and the attachment hole 14h of the attachment portion 14 (see FIGS. 5, 9, 11, and the like). The opening portion 53 penetrates through the base member 41S in the Z direction. The fastening member 95 (for example, a screw or a bolt) described below passes through the opening portion 53. This content will be described later. The opening portion 53 may be an opening formed in a notched shape through which the fastening member 95 (for example, a screw or a bolt) can be inserted.

The base member 41S may have a rib 51L protruding from the flat surface portion 51 in the +Z direction around the opening portion 53. The rib 51L can support the attachment portion 14 from the −Z direction (see FIG. 9). Instead of the above example, the base member 41S may have a boss provided with the opening portion 53.

### First Auxiliary Member

The routing board 40S may further include one or more first auxiliary members 46 as necessary. As also illustrated in FIG. 5, the first auxiliary member 46 is a support member that assists three-dimensional routing of some bus bars 42 (for example, the bus bars 42 corresponding to “three-dimensional routing members” described below). The first auxiliary member 46 supports the bus bar 42 from the −Z direction side. The first auxiliary member 46 supports a second connection portion 62 of the bus bar 42 at a position away from a first connection portion 61 of the bus bar 42 (for example, a position away in the Z direction). The first auxiliary member 46 is made of, for example, a synthetic resin and has an insulating property.

The first auxiliary member 46 may integrally support two or more bus bars 42. For example, in the present embodiment, a bus bar 42E described below and a bus bar 42I described below are supported by one first auxiliary member 46. For example, in the present embodiment, a bus bar 42F described below and a bus bar 42H described below are supported by one first auxiliary member 46.

The first auxiliary member 46 may integrally support the bus bar 42 and the connection bus bar 47. For example, in the present embodiment, a connection bus bar 47A described below and a bus bar 42W described below are supported by one first auxiliary member 46 (see FIGS. 1, 2, and 3).

The first auxiliary member 46 is fixed to the base member 41S of the routing board 40S by a snap-fit or the like, for example. When the first auxiliary member 46 and the base member 41S are fixed, assemblability of the first structure 1A is improved. Thereafter, any one of the bus bars 42 supported by the first auxiliary member 46 is connected to the bus bar 42 (for example, the bus bar 42 (such as the bus bars 42A, 42B, 42C, and 42D) corresponding to “horizontal routing members” described below) supported by the base member 41S via the fastening member 43.

The first auxiliary member 46 may have an opening. Any one of the bus bars 42 supported by the first auxiliary member 46 is exposed from the first auxiliary member 46 toward the base member 41S on the −Z direction side through the opening. For example, any bus bar exposed from the first auxiliary member 46 is connected to the bus bar 42 supported by the base member 41S via the fastening member 43.

The first auxiliary member 46 is disposed between the base member 41S and the bus bar 42 (such as the bus bars 42E, 42F, 42G, 42H, 42I, 42V, and 42W) corresponding to the “three-dimensional routing members” described below when viewed from the X direction or the Y direction.

### <2.3.2 Bus Bar>

Next, the bus bar 42 included in the routing board 40S will be described. The bus bar 42 is a routing member (electrical connection member) of the electrical connection unit 100. The bus bar 42 included in the routing board 40S is electrically connected to, for example, at least one electronic component 10S included in the plurality of electronic components 10S. For example, each of some bus bars 42 electrically connects two electronic components 10 included in the plurality of electronic components 10 (for example, the plurality of electronic components 10S). The bus bar 42 is made of metal (for example, copper, a copper alloy, aluminum, or an aluminum alloy) and has conductivity.

In the present embodiment, the plurality of bus bars 42 in the first structure 1A include, for example, 11 bus bars 42A, 42B, 42C, 42D, 42E, 42F, 42G, 42H, 42I, 42V, and 42W (see FIGS. 5 and 6).

As also illustrated in FIG. 6, four bus bars 42A, 42B, 42C, and 42D are disposed to be arranged at intervals in the horizontal direction. The four bus bars 42A, 42B, 42C, and 42D include portions disposed on the same plane. The four bus bars 42A, 42B, 42C, and 42D are supported by the flat surface portion 51 of the base member 41S. In the present disclosure, the phrase “the bus bar is supported by the flat surface portion” is not limited to a case where the bus bar 42 is accommodated in the accommodation portion 55, and may include a case where the bus bar 42 is attached to the first surface 51a or the second surface 51b of the flat surface portion 51. The four bus bars 42A, 42B, 42C, and 42D are integrated with the base member 41S through insert molding.

At least a part of each bus bar 42 has a plate shape extending in the horizontal direction.

For example, at least a part of each of the four bus bars 42A, 42B, 42C, and 42D is accommodated in the accommodation portion 55 and extends along the flat surface portion 51. That is, at least a part of each of the four bus bars 42A, 42B, 42C, and 42D extends along the first surface 51a of the flat surface portion 51. At least a part of each of the four bus bars 42A, 42B, 42C, and 42D extends in the horizontal direction in the accommodation portion 55. Hereinafter, a portion of each of the four bus bars 42, which extends in a plate shape extending in the horizontal direction, may be referred to as the “horizontal plate portion 42p”. The horizontal plate portion 42p is an example of a “plate portion”. The four bus bars 42A, 42B, 42C, and 42D are members forming energization paths in the horizontal direction. The four bus bars 42A, 42B, 42C, and 42D may be referred to as the “horizontal routing members”. At least a part of the bus bar 42 corresponding to the “horizontal routing member” extends in the horizontal direction in the accommodation portion 55. As a result, the energization path in the horizontal direction is formed in the routing board 40S.

For example, the four bus bars 42A, 42B, 42C, and 42D are located on the first side (−Z direction side) with respect to the electronic component 10 of the first structure 1A. That is, the four bus bars 42A, 42B, 42C, and 42D are located on a side opposite to the ceiling wall portion 72 of the metal cover 70 with respect to the electronic component 10 of the first structure 1A.

As also illustrated in FIG. 5, seven bus bars 42E, 42F, 42G, 42H, 42I, 42V, and 42W are three-dimensionally arranged at intervals. The seven bus bars 42E, 42F, 42G, 42H, 42I, 42V, and 42W are supported by the first auxiliary members 46. The first connection portion 61 and the second connection portion 62 of each of the seven bus bars 42E, 42F, 42G, 42H, 42I, 42V, and 42W extend in the horizontal direction on the first auxiliary member 46. The seven bus bars 42E, 42F, 42G, 42H, 42I, 42V, and 42W are the bus bars 42 forming energization paths in the vertical direction. The seven bus bars 42E, 42F, 42G, 42H, 42I, 42V, and 42W may be referred to as the “three-dimensional routing members”. In the bus bar 42 corresponding to the “three-dimensional routing member”, the second connection portion 62 of the bus bar 42 is at a position away from the first connection portion 61 (for example, a position away in the Z direction). As a result, the energization path in the vertical direction is formed in the routing board 40S.

As illustrated in FIGS. 5 to 7, each bus bar 42 includes, for example, the first connection portion 61, the second connection portion 62, and an extending portion 63.

The first connection portion 61 is located in the middle of the bus bar 42 or at a first end of the bus bar 42. The first connection portion 61 is a portion connected to the electronic component 10 (for example, the electronic component 10S) directly or via the connection component 20. In addition, instead of the above example, the first connection portion 61 may be connected to another bus bar 42 (for example, a bus bar 42 different from the bus bar 42 connected to the electronic component 10). Instead of the above example, the first connection portion 61 (for example, the first connection portion 61 of the bus bar 42W) may be connected to an external connection bus bar 99 (see FIGS. 1, 2, and 3).

Further, the first connection portion 61 includes, for example, a portion overlapping the connection component 20 when viewed from the Z direction. The first connection portion 61 is adjacent to the connection component 20 in the Z direction and is connected to the connection component 20 from the Z direction. Instead of the above example, for example, the first connection portion 61 may be adjacent to the terminal 13 of the electronic component 10 in the Z direction and directly connected to the terminal 13 of the electronic component 10 from the Z direction.

The second connection portion 62 is located in the middle of the bus bar 42 or at a second end of the bus bar 42. The second connection portion 62 is a portion connected to the electronic component 10 (for example, the electronic component 10S) directly or via the connection component 20. Instead of the above example, the second connection portion 62 may be connected to another bus bar 42 (for example, a bus bar 42 different from the bus bar 42 connected to the electronic component 10). In addition, instead of the above example, the second connection portion 62 may be connected to the connection bus bar 47 or the external connection bus bar 99 (see FIGS. 1 and 2). For example, the second connection portion 62 is connected to external equipment via the external connection bus bar 99. The external connection bus bar 99 is an example of an “external connection component”.

The extending portion 63 extends over the first connection portion 61 and the second connection portion 62. The extending portion 63 is provided between the first connection portion 61 and the second connection portion 62. The extending portion 63 connects the first connection portion 61 to the second connection portion 62.

In the present embodiment, the horizontal plate portion 42p described above includes at least the entire first connection portion 61 and a part of the extending portion 63. That is, in the four bus bars 42A, 42B, 42C, and 42D, at least the entire first connection portion 61 and a part of the extending portion 63 are accommodated in the accommodation portion 55 and located on the same plane.

Hereinafter, some routing examples of the bus bars 42 in the routing board 40S will be described. The plurality of electronic components 10S include two electronic components 10A and 10B. The plurality of connection components 20 include four connection components 20A, 20B, 20C, and 20D.

First, the four bus bars 42A, 42B, 42C, and 42D will be described.

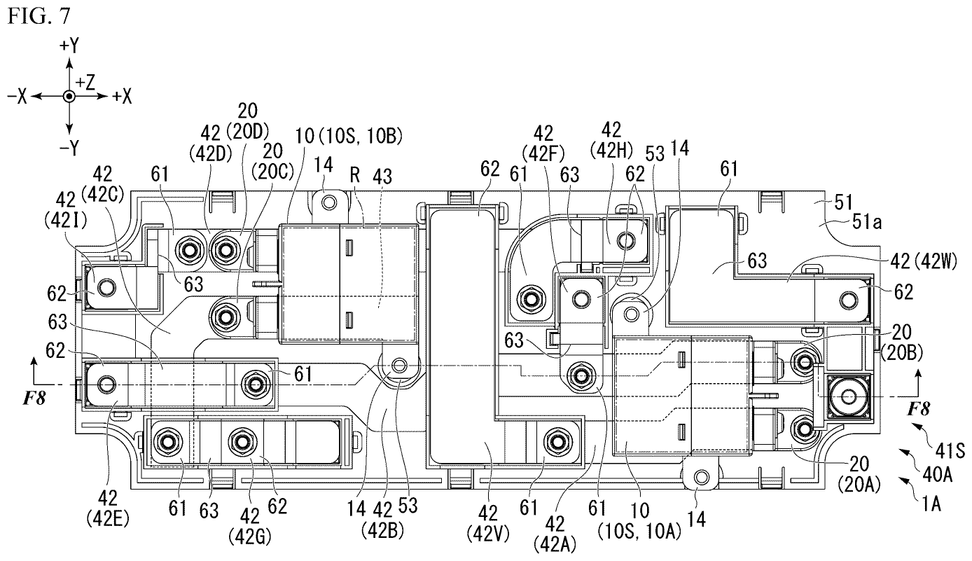

The bus bar 42A includes the first connection portion 61, the second connection portion 62, and the extending portion 63. The first connection portion 61 is connected to the terminal 13A of the electronic component 10A via the connection component 20A. The second connection portion 62 is disposed on the −X direction side of the first connection portion 61, and is connected to the external connection bus bar 99. The external connection bus bar 99 is supported by the first auxiliary member 46 from the −Z direction. The extending portion 63 is accommodated in the accommodation portion 55 to extend over both sides of a region R through the region R overlapping the electronic component 10A when viewed from the Z direction (see FIG. 7).

The bus bar 42B includes the first connection portion 61, two second connection portions 62, and the extending portion 63. The first connection portion 61 is connected to the terminal 13B of the electronic component 10A via the connection component 20B. The respective second connection portions 62 are disposed on the −X direction side of the first connection portion 61 and are connected to other bus bars 42 (bus bars 42E and 42F). The other bus bars 42(bus bars 42E and 42F) are supported by the first auxiliary members 46 from the −Z direction.

The bus bar 42C includes the first connection portion 61, the second connection portion 62, and the extending portion 63. The first connection portion 61 is connected to the terminal 13B of the electronic component 10B via the connection component 20C. The second connection portion 62 is disposed on the −Y direction side of the first connection portion 61 and is connected to another bus bar 42 (bus bar 42G). The another bus bar 42 (bus bar 42G) is supported by the first auxiliary member 46 from the −Z direction.

The bus bar 42D includes the first connection portion 61, two second connection portions 62, and two extending portions 63. The first connection portion 61 is connected to the terminal 13A of the electronic component 10B via the connection component 20D. One of the two second connection portions 62 is disposed on the +X direction side of the first connection portion 61 and is connected to another bus bar 42 (bus bar 42H). The other of the two second connection portions 62 is disposed on the −X direction side of the first connection portion 61 and is connected to another bus bar 42 (bus bar 42I). The other bus bars 42 (bus bars 42H and 42I) are supported by the first auxiliary members 46 from the −Z direction.

Next, the seven bus bars 42E, 42F, 42G, 42H, 42I, 42V, and 42W will be described. The seven bus bars 42E, 42F, 42G, 42H, 42I, 42V, and 42W perform three-dimensional routing in a state of being supported by the first auxiliary members 46 from the −Z direction.

The bus bar 42E includes the first connection portion 61, the second connection portion 62, and the extending portion 63. The first connection portion 61 of the bus bar 42E is connected to the second connection portion 62 of the bus bar 42A. The second connection portion 62 is disposed on the +Z direction side of the first connection portion 61 and is connected to the external connection bus bar 99. The second connection portion 62 of the bus bar 42E is exposed from the metal cover 70 toward the +Z direction side through an insertion portion 75 (described below) of the metal cover 70 (see FIGS. 2 and 3).

The bus bar 42F includes the first connection portion 61, the second connection portion 62, and the extending portion 63. The first connection portion 61 of the bus bar 42F is connected to the second connection portion 62 of the bus bar 42B. The second connection portion 62 is disposed on the +Z direction side of the first connection portion 61 and is connected to the external connection bus bar 99. The bus bar 42F may be omitted. The second connection portion 62 of the bus bar 42F is exposed from the metal cover 70 toward the +Z direction side through the insertion portion 75 (described below) of the metal cover 70 (see FIGS. 2 and 3).

The bus bar 42G includes the first connection portion 61, the second connection portion 62, and the extending portion 63. The first connection portion 61 of the bus bar 42G is connected to the second connection portion 62 of the bus bar 42C. The second connection portion 62 is disposed on the +Z direction side of the first connection portion 61 and is connected to a connection bus bar 47B. The second connection portion 62 of the bus bar 42G is exposed from the metal cover 70 toward the +Z direction side (see FIGS. 2 and 3) through the insertion portion 75 (described below) of the metal cover 70.

The bus bar 42H includes the first connection portion 61, the second connection portion 62, and the extending portion 63. The first connection portion 61 of the bus bar 42H is connected to the second connection portion 62 of the bus bar 42D. The second connection portion 62 is disposed on the +Z direction side of the first connection portion 61 and is connected to the external connection bus bar 99. The bus bar 42H may be omitted. The second connection portion 62 of the bus bar 42H is exposed from the metal cover 70 toward the +Z direction side (see FIGS. 2 and 3) through the insertion portion 75 (described below) of the metal cover 70.

The bus bar 42I includes the first connection portion 61, the second connection portion 62, and the extending portion 63. The first connection portion 61 of the bus bar 42I is connected to the second connection portion 62 of the bus bar 42D. The second connection portion 62 is disposed on the +Z direction side of the first connection portion 61 and is connected to the external connection bus bar 99. The second connection portion 62 of the bus bar 42I is exposed from the metal cover 70 toward the +Z direction side (see FIGS. 2 and 3) through the insertion portion 75 (described below) of the metal cover 70.

The bus bar 42V includes the first connection portion 61, the second connection portion 62, and the extending portion 63. The first connection portion 61 of the bus bar 42V is connected to the second connection portion 62 of the bus bar 42A. The second connection portion 62 is disposed on the +Z direction side of the first connection portion 61 and is connected to the external connection bus bar 99. The second connection portion 62 of the bus bar 42V is exposed from the metal cover 70 toward the +Z direction side (see FIGS. 2 and 3) through the insertion portion 75 (described below) of the metal cover 70.

The bus bar 42W includes the first connection portion 61, the second connection portion 62, and the extending portion 63. The first connection portion 61 and the second connection portion 62 of the bus bar 42W are connected to the external connection bus bars 99. The second connection portion 62 is disposed on the +Z direction side of the first connection portion 61. The first connection portion 61 and the second connection portion 62 of the bus bar 42W are exposed from the metal cover 70 toward the +Z direction side through the insertion portions 75 (described below) of the metal cover 70 (see FIGS. 2 and 3).

The bus bar 42V and the external connection bus bar 99 may be directly connected to each other by using a fastening member (for example, a bolt or a screw), welding, or the like. Since the second connection portion 62 of the bus bar 42V is exposed toward the +Z direction side (see FIG. 2), the external connection bus bar 99 can be connected from the +Z direction side even after the first structure 1A is fixed to the metal cover 70. The bus bar 42W and the external connection bus bars 99 may be directly connected to the bus bar 42W by using fastening members (for example, bolts or screws), welding, or the like. Since the first connection portion 61 and the second connection portion 62 of the bus bar 42W are exposed toward the +Z direction side (see FIG. 2), the external connection bus bars 99 can be connected from the +Z direction side even after the first structure 1A is fixed to the metal cover 70.

### <2.3.3 Fastening Member>

Next, the fastening member 43 will be described.

FIG. 8 is a cross-sectional view of a structure taken along line F8-F8 in FIG. 7. The fastening member 43 is a component for fixing the bus bar 42 to the connection component 20 corresponding to the bus bar 42. In addition, instead of the above example, the fastening member 43 may be a component for fixing the connection bus bar 47 or the external connection bus bar 99, and the bus bar 42. The fastening member 43 is, for example, a caulking bolt fixed to the bus bar 42. The fastening member 43 is an example of a “fastening portion”. In FIG. 7, a third heat transfer member 92C (described below) and a fourth heat transfer member 92D (described below) in FIG. 3 are omitted.

In some bus bars 42 of the present embodiment, at least one of the first connection portion 61 and the second connection portion 62 of the bus bar 42 has a through-hole 43h (see FIG. 6). The through-hole 43h penetrates through the bus bar 42 in the Z direction. The fastening member 43 is, for example, a bolt having a shaft 43a and a head 43b. A circumferential surface of the shaft 43a has a screw groove. The head 43b has a diameter larger than that of the shaft 43a. The head 43b of the fastening member 43 is caulked and fixed to the bus bar 42 in a state in which the shaft 43a passes through the through-hole 43h of the bus bar 42. With this fixation, the fastening member 43 is electrically and physically connected to the bus bar 42 in a state in which the shaft 43a protrudes in the +Z direction from the through-hole 43h of the bus bar 42. The fastening member 43 is not limited to caulking fixation, and may be fixed to the bus bar 42 through welding or other methods.

In the present embodiment, the connection component 20 is attached to the fastening member 43 from the Z direction after being fixed to the electronic component 10 via the fastening member 96. For example, the shaft 43a of the fastening member 43 is inserted into the attachment hole 22h of the second portion 22 in the connection component 20. The engagement member 44 (for example, a nut) is engaged with the shaft 43a of the fastening member 43 protruding from the attachment hole 22h of the second portion 22 of the connection component 20. The engagement member 44 is attached to the shaft 43a in the Z direction. With such engagement, the second portion 22 of the connection component 20 is fixed to the fastening member 43.

### Exposure Structure of Four Bus Bars on Upper Surface Side

FIG. 9 additionally illustrates the metal cover 70 and the second structure 1B in addition to the cross-sectional view illustrated in FIG. 8. In the present embodiment, at least a part of each of the four bus bars 42A, 42B, 42C, and 42D is exposed to an upper surface side of the base member 41S. For example, in the four bus bars 42A, 42B, 42C, and 42D, the first connection portion 61, the second connection portion 62, and the extending portion 63 are exposed to the outside of the base member 41S on the upper surface side of the base member 41S (a first surface 51a side of the flat surface portion 51). For example, the extending portion 63 of the bus bar 42 is exposed to the outside of the base member 41S on the upper surface side of the base member 41S at least over the entire length between the first connection portion 61 and the second connection portion 62.

### Exposure Structure of Four Bus Bars on Lower Surface Side

In the present embodiment, at least a part of each of the four bus bars 42A, 42B, 42C, and 42D is exposed to a lower surface side of the base member 41S. For example, in the four bus bars 42A, 42B, 42C, and 42D, the entire first connection portion 61 and at least a part of the extending portion 63 are exposed to the outside of the base member 41S on the lower surface side of the base member 41S (a second surface 51b side of the flat surface portion 51). In the present embodiment, a gap S1 is formed between the flat surface portion 51 of the base member 41S and the external cooler CM. The bus bar 42 includes an exposed portion 42u exposed to the gap S1. The exposed portion 42u includes, for example, the entire first connection portion 61 and at least a part of the extending portion 63. For example, the exposed portion 42u may be covered with the insulating sheet 91 (first insulating sheet 91A).

### <3. Detailed Constitution of Second Structure>

Next, the constitution of the second structure 1B included in the electrical connection unit 100 will be described in detail.

### <3.1 Electronic Component 10T>

In the present embodiment, the plurality of electronic components 10 included in the electrical connection unit 100 include the electronic component 10T. The electronic component 10T is an electronic component whose amount of heat generation during energization is smaller than that of the electronic component 10S. The electronic component 10T is, for example, a connector, a fuse, a capacitor, a branch component, any of various sensors (for example, a current sensor or a voltage sensor), an electronic control unit, or an electronic component unit in which two or more of these are unitized. However, the type of the electronic component 10T is not limited to the above example.

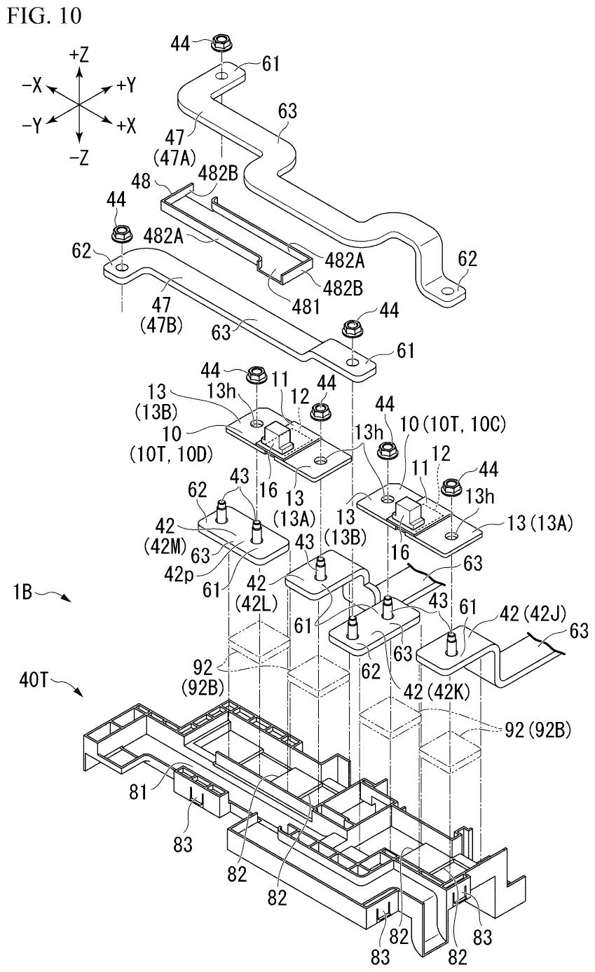

As illustrated in FIG. 10, the electronic component 10T in the present embodiment is, for example, a current sensor (for example, a current sensor including a shunt resistor). The electronic component 10T includes an output port 16 protruding in the +Z direction. When external equipment (for example, a control board or a measuring instrument) is attached to the output port 16, a current value of a current flowing through the electrical connection unit 100 (for example, a current flowing through the first structure 1A) is monitored. For example, the electronic component 10T is an electronic component in which two terminals 13 are separately disposed at both ends of the electronic component 10T in the horizontal direction. The electronic component 10T includes, for example, a case 11, a component body 12, the plurality of terminals 13 (a terminal 13A and a terminal 13B), and the output port 16. Note that, among the constitutions of the electronic component 10T, constitutions having functions similar to those of the electronic component 10S are denoted by the same reference numbers. In this case, in the description regarding the electronic component 10T, the “electronic component 10S” may be replaced with the “electronic component 10T” in the description regarding the electronic component 10S described above.

In the electronic component 10T, the terminal 13A and the terminal 13B are disposed apart from each other in the horizontal direction (for example, the X direction). Each terminal 13 has an attachment hole 13h through which a fastening member 43 (for example, a screw or a bolt) passes. The attachment hole 13h is open in the Z direction. In the electronic component 10T, one of the terminal 13A and the terminal 13B is an example of a “third terminal”. The other of the terminal 13A and the terminal 13B is an example of a “fourth terminal”.

### <3.2 Cover Member>

The cover member 40T in the second structure 1B will be described in detail.

The cover member 40T covers a part of the bus bar 42 in the second structure 1B. The cover member 40T includes, for example, a wall portion 81 and one or more locking portions 83. The cover member 40T is made of, for example, a synthetic resin and has an insulating property.

The wall portion 81 is, for example, a wall having a plate-like portion extending in the horizontal direction. The wall portion 81 extends so as to cover a lower surface of an extending portion 63 (described below) of the connection bus bar 47 in the horizontal direction (for example, the X direction). The wall portion 81 is not limited to a wall portion extending in the horizontal direction, and may be a grid-shaped wall portion formed by a plurality of ribs extending in the Z direction. In the present embodiment, the fastening member 43 fixed to the bus bar 42 is disposed on the wall portion 81. Further, the wall portion 81 may partially have a step. For example, in the present embodiment, two connection bus bars 47 are attached to the bus bar 42 of the second structure 1B. The two connection bus bars 47 three-dimensionally cross each other due to the step of the wall portion 81.

For example, the cover member 40T may include an accommodation portion 82 that is open toward the +Z direction side. The accommodation portion 82 is a through-hole penetrating through the wall portion 81 in the Z direction. The accommodation portion 82 has an outer shape corresponding to a shape of the heat transfer member 92 (for example, a second heat transfer member 92B) described below when viewed from the Z direction. The accommodation portion 82 surrounds and accommodates the second heat transfer member 92B (described below) adhering to the ceiling wall portion 72 (see FIGS. 2 and 10). Note that the second heat transfer member 92B indicated by an imaginary line in FIG. 10 can be accommodated in the accommodation portion 82.

### (Locking Portion)

The locking portion 83 is used for locking the metal cover 70 and the second structure 1B. Examples of the locking portion 83 include a fitting claw. The fitting claw includes an arm portion 83AR extending in the −Z direction from the wall portion 81 and a protruding portion 83PR protruding as a part of the arm portion 83AR (see FIG. 2). The protruding portion 83PR protrudes from the arm portion 83AR in a direction intersecting an extending direction (−Z direction) of the arm portion 83AR. In the present embodiment, the protruding portion 83PR protrudes toward the metal cover 70 and is locked to a holding portion 74 described below (see FIG. 1). For example, the protruding portion 83PR has an inclined surface inclined with respect to the Z direction. In work of attaching the second structure 1B to the metal cover 70, when the locking portion 83 approaches the metal cover 70, the protruding portion 83PR is pressed by the metal cover 70, and the arm portion 83AR is thus elastically deformed in a predetermined direction. Then, once the protruding portion 83PR reaches the holding portion 74, the arm portion 83AR is recovered from the deformed state, whereby the protruding portion 83PR is locked to the holding portion 74.

### <3.3 Bus Bar>

Next, the bus bar 42 in the second structure 1B will be described. The plurality of bus bars 42 in the second structure 1B include, for example, four bus bars 42J, 42K, 42L, and 42M (see FIG. 10).

Among the plurality of bus bars 42 in the second structure 1B, the bus bar 42 electrically connected to the electronic component 10T is an example of a “second routing member”. In the present embodiment, the four bus bars 42J, 42K, 42L, and 42M are the “second routing members” (see FIG. 10).

The four bus bars 42J, 42K, 42L, and 42M are disposed apart from each other in the horizontal direction. The four bus bars 42J, 42K, 42L, and 42M are supported by the wall portion 81 of the cover member 40T. For example, in a state in which movement of the bus bar 42 is restricted by a rib or the like of the cover member 40T, the four bus bars 42 (bus bars 42J, 42K, 42L, and 42M) are arranged in the horizontal direction at intervals. The bus bar 42 is disposed so as to partially overlap the second heat transfer member 92B when viewed from the Z direction. With such an arrangement, a heat transfer path from the bus bar 42 to the metal cover 70 is formed via the second heat transfer member 92B. The bus bar 42 is disposed immediately below the terminal 13 of the electronic component 10, for example.

In the present embodiment, the bus bar 42K and the bus bar 42M have a plate shape extending in the horizontal direction over the entire length. The bus bar 42K and the bus bar 42M include a horizontal plate portion 42p. In the present embodiment, the plurality of electronic components 10T include two electronic components 10C and 10D.

The four bus bars 42J, 42K, 42L, and 42M are routing members (electrical connection members) at least partially covered by the cover member 40T. For example, the bus bar 42 in the second structure 1B is electrically connected to at least one electronic component 10 included in the plurality of electronic components 10T. For example, each of some bus bars 42 electrically connects two electronic components 10 included in the plurality of electronic components 10 (for example, the plurality of electronic components 10T). The plurality of electronic components 10T in the second structure 1B are formed apart from each other in the horizontal direction (for example, the X direction).

For example, four bus bars 42J, 42K, 42L, and 42M and the plurality of electronic components 10T are attached to the cover member 40T from the +Z direction. The fastening members 43 are fixed to the four bus bars 42J, 42K, 42L, and 42M. Note that the fastening member 43 is similar to the fastening member 43 described in the routing board 40S, and thus repeated description will be omitted. The plurality of fastening members 43 may be provided integrally with the cover member 40T through, for example, insert molding or the like. The plurality of fastening members 43 may be fixed to the cover member 40T by a method other than insert molding.

The four bus bars 42J, 42K, 42L, and 42M will be described.

A first connection portion 61 of the bus bar 42J is attached to the cover member 40T from the +Z direction side, so that a lower surface of the bus bar 42J is covered. The first connection portion 61 of the bus bar 42J is physically and electrically connected to the terminal 13A of the electronic component 10C. For example, the terminal 13A of the electronic component 10C is connected to the first connection portion 61 via the fastening member 43 by being attached to the first connection portion 61 of the bus bar 42J from the +Z direction side.

A first connection portion 61 of the bus bar 42K is attached to the cover member 40T from the +Z direction side, so that a lower surface of the bus bar 42K is partially covered. At this time, a part of the bus bar 42K is exposed from the accommodation portion 82 toward the −Z direction. In the present embodiment, the second heat transfer member 92B accommodated in the accommodation portion 82 is disposed immediately below the first connection portion 61 of the bus bar 42K. The first connection portion 61 of the bus bar 42K is physically and electrically connected to the terminal 13B of the electronic component 10C via the fastening member 43. A second connection portion 62 of the bus bar 42K is connected to the connection bus bar 47 via the fastening member 43.

A first connection portion 61 of the bus bar 42L is attached to the cover member 40T from the +Z direction side, so that a lower surface of the bus bar 42L is partially covered. A first connection portion 61 of the bus bar 42L is physically and electrically connected to the terminal 13A of the electronic component 10D. For example, the terminal 13A of the electronic component 10D is connected to the first connection portion 61 via the fastening member 43 by being attached to the first connection portion 61 of the bus bar 42L from the +Z direction side.

A first connection portion 61 of the bus bar 42M is attached to the cover member 40T from the +Z direction side, so that a lower surface of the bus bar 42M is partially covered. At this time, a part of the bus bar 42M is exposed from the accommodation portion 82 toward the −Z direction. In the present embodiment, the second heat transfer member 92B accommodated in the accommodation portion 82 is disposed immediately below the first connection portion 61 of the bus bar 42M. The first connection portion 61 of the bus bar 42M is physically and electrically connected to the terminal 13B of the electronic component 10D via the fastening member 43. A second connection portion 62 of the bus bar 42M is connected to the connection bus bar 47 via the fastening member 43.

### <4. Connection Bus Bar>

Next, the connection bus bar 47 will be described.

As illustrated in FIG. 10, the connection bus bar 47 is a routing member for connecting the first structure 1A to the second structure 1B and electrically connecting the first structure 1A to the second structure 1B. At least one electronic component 10 included in the plurality of electronic components 10S included in the first structure 1A and at least one electronic component 10 included in the plurality of electronic components 10T included in the second structure 1B are electrically connected via the connection bus bar 47. In the present embodiment, the plurality of connection bus bars 47 include two connection bus bars 47A and 47B.

The connection bus bar 47 includes, for example, a first connection portion 61, a second connection portion 62, and the extending portion 63. The first connection portion 61, the second connection portion 62, and the extending portion 63 are similar to the first connection portion 61, the second connection portion 62, and the extending portion 63 described in the routing board 40S, and thus repeated description will be omitted.

The connection bus bar 47A includes the first connection portion 61, the second connection portion 62, and the extending portion 63. In the connection bus bar 47A, the second connection portion 62 is located on the −Z direction side of the first connection portion 61. The extending portion 63 extends from the first connection portion 61 to the second connection portion 62, and is partially bent. The second connection portion 62 of the connection bus bar 47A is supported by one first auxiliary member 46 together with the bus bar 42W.

The first connection portion 61 of the connection bus bar 47A is attached to the second connection portion 62 of the bus bar 42M from the +Z direction side, and is connected to the bus bar 42M via the fastening member 43. The external connection bus bar 99 is attached to the second connection portion 62 from the +Z direction side and is connected to the second connection portion 62 (see FIG. 1).

The connection bus bar 47B includes the first connection portion 61, the second connection portion 62, and the extending portion 63. In the connection bus bar 47B, the second connection portion 62 is located on the −Z direction side of the first connection portion 61. The extending portion 63 extends from the first connection portion 61 to the second connection portion 62, and is partially bent. Due to the bending, a part of the connection bus bar 47A (for example, a part of the extending portion 63) three-dimensionally intersects the connection bus bar 47B.

The first connection portion 61 of the connection bus bar 47B is attached to the second connection portion 62 of the bus bar 42K from the +Z direction side, and is connected to the bus bar 42M via the fastening member 43. The second connection portion 62 is attached to the second connection portion 62 of the bus bar 42G from the +Z direction side, and is connected to the bus bar 42G via the fastening member 43 (see FIG. 2).

### <5. Second Auxiliary Member>

As illustrated in FIG. 10, when two connection bus bars 47 are attached to the bus bars 42 (for example, the bus bars 42K and 42M) of the second structure 1B, the two connection bus bars 47 may be adjacent to each other in the Z direction. In this case, the second auxiliary member 48 is disposed between the two adjacent connection bus bars 47. The second auxiliary member 48 electrically insulates between the two connection bus bars 47 adjacent to each other in the Z direction. The second auxiliary member 48 is made of, for example, a synthetic resin and has an insulating property. The second auxiliary member 48 is slidable between the two adjacent connection bus bars 47.

The second auxiliary member 48 includes a support wall 481 and a restricting portion 482.

The support wall 481 is, for example, a plate-shaped wall portion extending in the horizontal direction. The support wall 481 is an insulating wall that electrically insulates between the two connection bus bars 47 adjacent to each other in the Z direction. The support wall 481 forms a main portion of the second auxiliary member 48. The support wall 481 has an outer shape corresponding to a region where the two connection bus bars 47 overlap each other when viewed from the Z direction.

The restricting portion 482 is, for example, a rib extending in the +Z direction from the support wall 481. The restricting portion 482 is at a position deviated from the region where the two connection bus bars 47 overlap each other when viewed from the Z direction. The restricting portion 482 includes a first restricting portion 482A and a second restricting portion 482B. The first restricting portion 482A is a rib extending in the +Z direction across from the −X direction to the +X direction. The second restricting portion 482B is a rib extending in the +Z direction across from the −Y direction to the +Y direction. As the first restricting portion 482A and the second restricting portion 482B are provided, the second auxiliary member 48 is slid according to movement of one (for example, the connection bus bar 47A) of the two adjacent connection bus bars 47 in the horizontal direction. The second auxiliary member 48 may be disposed in an inverted manner. In other words, the restricting portion 482 may be a rib extending in the −Z direction from the support wall 481.

### <6. Constitution of Metal Cover>

Next, a constitution of the metal cover 70 will be described.

The metal cover 70 is a member for securing rigidity of the electrical connection unit 100 and enhancing the heat dissipation property of the electrical connection unit 100. At least a part of the metal cover 70 is made of metal (for example, aluminum or an aluminum alloy). The metal cover 70 is an example of a “heat dissipation member”. The metal cover 70 may be referred to as a “metal member” or a “rigid member”.

As illustrated in FIGS. 3 and 11, in the electrical connection unit 100, the metal cover 70 covers the first structure 1A from the +Z direction. At this time, a lower surface of the base member 41S of the first structure 1A (the second surface 51b of the flat surface portion 51) is not covered with the metal cover 70 but is exposed. The metal cover 70 only needs to cover most of a main portion (described below) of the first structure 1A, and a part of the first structure 1A may be exposed through the insertion portion 75.

The metal cover 70 includes the peripheral wall 71, the ceiling wall portion 72, a plurality of fixing portions 73, one or more holding portions 74, and the insertion portion 75. Since the metal cover 70 covers the first structure 1A from the +Z direction, rigidity of the metal cover 70 is higher than rigidity of the base member 41S. The peripheral wall 71 has a plate shape extending in the −Z direction from the ceiling wall portion 72. The peripheral wall 71 faces at least one electronic component 10S included in the plurality of electronic components 10S included in the first structure 1A when viewed from the X direction or the Y direction. For example, the peripheral wall 71 may be made of metal similarly to the ceiling wall portion 72. The peripheral wall 71 is an example of a “second plate portion”.

The peripheral wall 71 includes one or more holding portions 71h. The holding portion 71h is used for holding the metal cover 70 and the first structure 1A in a locked state by the locking portion 56. The holding portion 71h is at a position corresponding to the locking portion 56. The holding portion 71h is, for example, an opening provided in the peripheral wall 71. The holding portion 71h may be a recess provided in the peripheral wall 71. In addition, instead of the above example, the holding portion 71h may be a protrusion protruding from the peripheral wall 71 in a direction intersecting the extending direction (+Z direction) of the arm portion 56AR. When the locking portion 56 approaches the holding portion 71h, one end of the peripheral wall 71 presses the protruding portion 56PR and elastically deforms the arm portion 56AR in a predetermined direction. Then, once the protruding portion 56PR reaches the holding portion 71h, the arm portion 56AR is recovered from the deformed state, whereby the protruding portion 56PR and the holding portion 71h are locked. In the present embodiment, since the holding portion 71h is an opening, the protruding portion 56PR and an edge of the holding portion 71h are locked. As a result, the first structure 1A is maintained in a state of being attached to the metal cover 70 (see FIG. 2).

The ceiling wall portion 72 is a portion formed in a plate shape in the metal cover 70. The ceiling wall portion 72 has a plate shape extending in the horizontal direction, and has a substantially rectangular shape extending in the X direction when viewed from the Z direction. The ceiling wall portion 72 forms a main portion of the metal cover 70. In the present embodiment, the ceiling wall portion 72 has a size that covers the entire first structure 1A from the +Z direction. As a result, the plurality of electronic components 10S and the plurality of bus bars 42 included in the first structure 1A are covered by the ceiling wall portion 72 from above. The ceiling wall portion 72 faces an upper surface of the base member 41S (the first surface 51a of the flat surface portion 51). The ceiling wall portion 72, which is the main portion of the metal cover 70, is made of metal. The ceiling wall portion 72 is an example of a “first plate portion”.

The insertion portion 75 is a notch or an opening of the metal cover 70. The insertion portion 75 has an outer shape corresponding to a shape of the first auxiliary member 46 that supports the bus bar 42 or/and the connection bus bar 47 when viewed from the Z direction. In the present embodiment, some bus bars 42 are connected to the external connection bus bars 99 through the insertion portions 75 (see FIGS. 1 and 2). The connection bus bar 47 routes connection between the first structure 1A and the second structure 1B through the insertion portion 75 (see FIGS. 1 and 2). In the present embodiment, the metal cover 70 includes a plurality of insertion portions 75.

The ceiling wall portion 72 has the first surface 72a and the second surface 72b. The first surface 72a is a surface directed in the +Z direction. The first surface 72a is a flat surface extending in the horizontal direction. The first surface 72a faces the plurality of electronic components 10T included in the second structure 1B (see FIG. 9). The second surface 72b is located on a side opposite to the first surface 72a. The second surface 72b is a surface directed in the −Z direction. The second surface 72b is a flat surface extending in the horizontal direction. The second surface 72b faces the plurality of electronic components 10S included in the first structure 1A (see FIG. 9). The thickness direction (plate thickness direction) of the ceiling wall portion 72 is the Z direction.

The ceiling wall portion 72 includes the first end 72e1, the second end 72e2, the third end 72e3, and the fourth end 72e4 (see FIG. 3). The first end 72e1 and the second end 72e2 are a pair of ends of the metal cover 70 in the longitudinal direction, and are separated from each other in the X direction. The third end 72e3 and the fourth end 72e4 are a pair of ends of the metal cover 70 in a lateral direction, and are separated from each other in the Y direction.

The fixing portion 73 is a fixing portion for directly fixing the electronic component 10S included in the first structure 1A to the metal cover 70 without interposing the base member 41S therebetween. The fixing portion 73 is provided at a position corresponding to the attachment portion 14 of each of the plurality of electronic component 10S when viewed from the Z direction. For example, in the present embodiment, the attachment portion 14, the fixing portion 73, and the opening portion 53 are arranged on each of axes AX1, AX2, AX3, and AX4 (see FIGS. 5, 9, and 11). The fixing portion 73 is a columnar or prism-shaped boss protruding in the −Z direction from the ceiling wall portion 72 toward each of the plurality of electronic components 10S included in the first structure 1A. For example, the fixing portion 73 may be made of metal similarly to the ceiling wall portion 72.

The fixing portion 73 has the attachment hole 73h into which the fastening member 95 (for example, a screw or a bolt; and see FIG. 10) described below is inserted. The attachment hole 73h is open in the Z direction. The attachment hole 73h is an insertion hole through which the fastening member 95 passes. The attachment hole 73h is an example of a “first attachment hole”.

In the present embodiment, when viewed from a direction from the first structure 1A toward the ceiling wall portion 72 (for example, a direction along any one of the axes AX1, AX2, AX3, and AX4), the attachment portion 14 is located in a region deviated from the bus bar 42 included in the first structure 1A (see FIGS. 5, 7, 11, and the like).

### Holding Portion

As also illustrated in FIG. 2, the holding portion 74 is used for holding a locked state between the metal cover 70 and the second structure 1B by the locking portion 83. The holding portion 74 is at a position corresponding to the locking portion 83. The holding portion 74 includes a protruding portion 74PR. The protruding portion 74PR protrudes from a tip of the holding portion 74 in a direction intersecting the extending direction (−Z direction) of the arm portion 83AR. In the present embodiment, the protruding portion 74PR protrudes toward the second structure 1B. When the locking portion 83 approaches the holding portion 74, the protruding portion 74PR presses the protruding portion 83PR and elastically deforms the arm portion 83AR in a predetermined direction. Then, once the protruding portion 83PR reaches the holding portion 74, the arm portion 83AR is recovered from the deformed state, whereby the protruding portion 83PR and the protruding portion 74PR are locked. As a result, the cover member 40T of the second structure 1B is maintained in a state of being attached to the metal cover 70 (see FIG. 1).

In a case where a portion having an electrical main function of the first structure 1A is a main portion of the first structure 1A, the main portion of the first structure 1A is formed by connection between the electronic component 10S and the first connection portion 61 of the bus bar 42. In the present embodiment, the main portion of the first structure 1A is formed by the electronic component 10S and the above-described “first routing member” (see FIG. 6). At least the main portion of the first structure 1A is disposed on the −Z direction side of the metal cover 70 (see FIG. 9). At least the main portion of the first structure 1A is disposed on the −Z direction side of the ceiling wall portion 72 of the metal cover 70 (see FIG. 9). In other words, at least one electronic component 10S included in the plurality of electronic components 10S is disposed on the −Z direction side of the metal cover 70. In addition, the bus bar 42 of the first structure 1A is located on a side (−Z direction side) opposite to the ceiling wall portion 72 of the metal cover 70 with respect to at least one electronic component 10S included in the plurality of electronic components 10S in the first structure 1A.

In a case where a portion having an electrical main function of the second structure 1B is set as a main portion of the second structure 1B, the main portion of the second structure 1B is formed by connection between the electronic component 10T and the first connection portion 61 of the bus bar 42 (see FIG. 10). In the present embodiment, the main portion of the second structure 1B is formed by the electronic component 10T and the above-described “second routing member” (see FIG. 10). At least the main portion of the second structure 1B is disposed on the +Z direction side of the metal cover 70. In other words, at least one electronic component 10T included in the plurality of electronic components 10T is disposed on the +Z direction side of the metal cover 70. At least the main portion of the second structure 1B is disposed on the +Z direction side of the ceiling wall portion 72 of the metal cover 70. In addition, the bus bar 42 of the second structure 1B is located on the same side (−Z direction side) as the ceiling wall portion 72 of the metal cover 70 with respect to at least one electronic component 10T included in the plurality of electronic components 10T in the second structure 1B.

### <7. Fastening Structure Between First Structure and Metal Cover>

As illustrated in FIG. 11, the metal cover 70 is disposed at a position covering the first structure 1A from the +Z direction. Thereafter, the first structure 1A is locked to the metal cover 70 by the locking portion 56 of the flat surface portion 51 of the base member 41S and the holding portion 71h of the peripheral wall 71 of the metal cover 70 (see FIG. 2). After the metal cover 70 and the first structure 1A are locked, the first structure 1A is supported by the metal cover 70 via the holding portion 71h. In FIG. 11, the first insulating sheet 91A (described below) and a first heat transfer member 92A (described below) in FIG. 3 are omitted.

After the locking, the fixing portion 73 is located between the attachment portion 14 of each of the plurality of electronic components 10S included in the first structure 1A and the ceiling wall portion 72. The plurality of electronic components 10S included in the first structure 1A are directly fixed to the metal cover 70 by the fastening members 95 passing through the opening portions 53 of the base member 41S (see FIGS. 2 and 11). In other words, in the present embodiment, the plurality of electronic components 10 (electronic components 10S) included in the first structure 1A are fixed to the metal cover 70 without sandwiching the base member 41S therebetween (that is, without interposing the base member 41S therebetween). In other words, each of the plurality of electronic components 10 included in the first structure 1A is individually fixed to the metal cover 70 by the fastening member 95 corresponding to each electronic component 10. In the first structure 1A, the electronic component 10S is electrically connected to the bus bar 42 via the connection component 20. The plurality of electronic components 10S are directly fixed to the metal cover 70, whereby the connection component 20 connected to the electronic component 10S and the bus bar 42 (the bus bar 42 indirectly fixed to the electronic component 10S via another connection component 20) are suspended on the metal cover 70.

<8. Connection between First Structure and Second Structure>

As also illustrated in FIG. 10, the plurality of bus bars 42 included in the second structure 1B are disposed on the wall portion 81, and the plurality of electronic components 10T are attached to the arbitrary bus bars 42 from the +Z direction side. Thereafter, as also illustrated in FIG. 2, one end of the connection bus bar 47 (connection bus bars 47A and 47B) is connected to any one of the plurality of bus bars 42 of the second structure 1B. In this way, the connection bus bar 47 is attached to the second structure 1B.

Thereafter, the second structure 1B in which the connection bus bar 47 is incorporated is locked to the metal cover 70 by the locking portion 83 of the cover member 40T and the holding portion 74 of the metal cover 70. After the metal cover 70 and the second structure 1B are locked, the second structure 1B is supported by the metal cover 70. The other end of the connection bus bar 47 is connected to the bus bar 42 of the first structure 1A or the external connection bus bar 99. At this time, in the second structure 1B, since the electronic component 10 and the bus bar 42 are not fixed to the cover member 40T, the connection bus bar 47 connected to the bus bar 42 of the second structure 1B is movable in the horizontal direction. Since the connection bus bar 47 is movable in the horizontal direction, an assembly tolerance occurring at the time of assembling the first structure 1A, the second structure 1B, and the metal cover 70 is absorbed. The first structure 1A and the second structure 1B are electrically connected in a state in which the assembly tolerance is absorbed by the connection bus bar 47.

### <9. Insulating Sheet and Heat Transfer Member>

Next, the insulating sheet 91 and the heat transfer member 92 will be described.

### <9.1 Insulating Sheet>

As also illustrated in FIG. 3, the insulating sheet 91 is an insulating member for insulating the bus bar 42. The insulating sheet 91 has a sheet shape extending in the horizontal direction. The insulating sheet 91 is made of, for example, a synthetic resin such as polyester or polyimide, and has an insulating property.

The insulating sheet 91 includes the first insulating sheet 91A and a second insulating sheet 91B. As also illustrated in FIG. 9, the first insulating sheet 91A has an outer shape corresponding to the lower surface of the base member 41S (the second surface 51b of the flat surface portion 51) in the Z direction. The first insulating sheet 91A is disposed on the −Z direction side of the first electronic component, and the first insulating sheet 91A is disposed between the external cooler CM and the routing board 40S. For example, in the present embodiment, the first insulating sheet 91A is attached to a lower surface of the routing board 40S. The first heat transfer member 92A is disposed immediately below the first insulating sheet 91A.

Instead of the above example, the first insulating sheet 91A may be disposed between the external cooler CM and the heat transfer member 92 (for example, the first heat transfer member 92A).

For example, the first insulating sheet 91A may have a notch or an opening for avoiding the opening portion 53 of the base member 41S (see FIG. 2). In addition, the first insulating sheet 91A may have a notch or an opening for avoiding the head 43b of the fastening member 43. For example, the first insulating sheet 91A may have a notch or an opening for avoiding the bus bar 42 (for example, the bus bar 42 corresponding to the “horizontal routing member”) supported by the base member 41S. Note that, in a case where the first heat transfer member 92A has an insulating property, and the necessary insulating property is secured by the first heat transfer member 92A, the first insulating sheet 91A may be omitted.

The second insulating sheet 91B is disposed immediately below the second heat transfer member 92B. The second heat transfer member 92B is disposed immediately below the bus bar 42 (bus bars 42K and 42M) exposed from the accommodation portion 82 in the −Z direction (see FIG. 10).

For example, the second insulating sheet 91B may have a notch or an opening for avoiding the head 43b of the fastening member 43. Note that, in a case where the second heat transfer member 92B has an insulating property, and the necessary insulating property is secured by the second heat transfer member 92B, the second insulating sheet 91B may be omitted.

### <9.2 Heat Transfer Member >

As also illustrated in FIG. 3, the heat transfer member 92 is a member for transferring heat generated by the electronic component 10 at the time of energization and/or heat (Joule heat) generated by the bus bar 42 itself at the time of energization to the external cooler CM and/or the metal cover 70. The heat transfer member 92 is, for example, a heat transfer sheet (for example, a thermally conductive silicone sheet) having elasticity. The heat transfer member 92 is made of a material having a higher thermal conductivity than the base member 41S and the cover member 40T. However, the heat transfer member 92 is not limited to the above example, and may be a heat transfer member made of a thermally conductive gel or another material.

The heat transfer member 92 includes the first heat transfer member 92A, the second heat transfer member 92B, the third heat transfer member 92C, and the fourth heat transfer member 92d.

The first heat transfer member 92A is disposed on the −Z direction side of the electronic component 10S, and the first heat transfer member 92A is disposed between the electronic component 10S and the external cooler CM. For example, the first heat transfer member 92A is disposed between the bus bar 42 connected to the electronic component 10S and the external cooler CM in the Z direction (see FIG. 9). In the present embodiment, the first heat transfer member 92A is partially provided for the routing board 40S to which the first insulating sheet 91A is attached. For example, the first heat transfer member 92A is disposed at a position overlapping a part (for example, the first connection portion 61) of the bus bar 42 (for example, the bus bar 42 corresponding to the “horizontal routing member”) supported by the base member 41S when viewed from the Z direction. For example, the first heat transfer member 92A is disposed below or immediately below the exposed portion 42u of the bus bar 42 (see FIG. 9). The first heat transfer member 92A transfers heat transferred from the electronic component 10S to the bus bar 42 and/or heat generated by the bus bar 42 from the bus bar 42 to the external cooler CM. In this way, the bus bar 42 of the first structure 1A is thermally connected to the external cooler CM by the first heat transfer member 92A.

In the present embodiment, a part of the first heat transfer member 92A is disposed at a position overlapping the head 43b of the fastening member 43 when viewed from the Z direction, and is in contact with the head 43b of the fastening member 43 (see FIG. 9). In this case, the first heat transfer member 92A easily transfers, from the fastening member 43 to the external cooler CM, heat transferred from the terminal 13 of the electronic component 10 to the connection component 20.

Further, the first heat transfer member 92A may have an outer shape corresponding to the lower surface of the base member 41S (the second surface 51b of the flat surface portion 51) and cover the lower surface.

The second heat transfer member 92B is disposed between the electronic component 10T and the ceiling wall portion 72 of the metal cover 70. For example, the second heat transfer member 92B is disposed immediately below the bus bar 42 (bus bars 42K and 42M) exposed from the accommodation portion 82 in the −Z direction (see FIG. 10). In the present embodiment, the second heat transfer member 92B is provided so as to cover the bus bar 42 (bus bars 42M and 42K) partially exposed from the accommodation portion 82 in the −Z direction (see FIGS. 2 and 10). The second heat transfer member 92B transfers, from the bus bar 42 to the metal cover 70, heat transferred from the electronic component 10T to the bus bar 42 and/or heat generated by the bus bar 42. In this way, the bus bar 42 of the second structure 1B is thermally connected to the metal cover 70 by the second heat transfer member 92B.

The third heat transfer member 92C is disposed between the electronic component 10S and the ceiling wall portion 72 of the metal cover 70. For example, the third heat transfer member 92C is disposed immediately above the case 11 of the electronic component 10S (see FIG. 8). In the present embodiment, the third heat transfer member 92C is provided so as to fill a gap between the electronic component 10S of the first structure 1A and the ceiling wall portion 72 (see FIG. 9). The third heat transfer member 92C transfers heat generated by the electronic component 10S from the case 11 to the metal cover 70. In this way, the electronic component 10S is thermally connected to the metal cover 70 by the third heat transfer member 92C. The third heat transfer member 92C may be sandwiched between the electronic component 10S and the peripheral wall 71 of the metal cover 70 in the horizontal direction.

The fourth heat transfer member 92D is disposed between the connection component 20 of the first structure 1A and the ceiling wall portion 72 of the metal cover 70. For example, the fourth heat transfer member 92D is disposed immediately above the first portion 21 of the connection component 20 (see FIG. 8). In the present embodiment, the fourth heat transfer member 92D is provided so as to fill a gap between the connection component 20 connected to the electronic component 10S and the ceiling wall portion 72 (see FIG. 9). The fourth heat transfer member 92D transfers heat generated by the electronic component 10S from the first portion 21 to the metal cover 70. In this way, the connection component 20 is thermally connected to the metal cover 70 by the fourth heat transfer member 92D. The fourth heat transfer member 92D may be sandwiched between the connection component 20 and the peripheral wall 71 of the metal cover 70 in the horizontal direction.

### <10. Advantages>

In the present embodiment, the electrical connection unit 100 includes the heat dissipation member (for example, the metal cover 70), the first electronic component (for example, the electronic component 10S), the first heat transfer member 92A, the second electronic component (for example, the electronic component 10T), and the second heat transfer member 92B. The first electronic component is disposed on the first side (for example, the −Z direction side) of the heat dissipation member. The first heat transfer member 92A is disposed on the first side (for example, the −Z direction side) of the first electronic component, and is disposed between the first electronic component and the external cooler CM. The second electronic component is disposed on the second side (for example, the +Z direction side) of the heat dissipation member. The second heat transfer member 92B is disposed between the second electronic component and the heat dissipation member.

According to such a constitution, heat generated in the first electronic component is released to the external cooler CM via the first heat transfer member 92A. In addition, heat generated in the second electronic component is released to the heat dissipation member via the second heat transfer member 92B. Therefore, thermal characteristics of the electrical connection unit 100 can be improved.

For example, heat of the first structure 1A disposed below the heat dissipation member is released to the external cooler CM via the first heat transfer member 92A. Heat of the second structure 1B disposed above the heat dissipation member is released to the heat dissipation member via the second heat transfer member 92B.

In the present embodiment, the electrical connection unit 100 further includes the third heat transfer member 92C disposed between the first electronic component and the heat dissipation member. According to such a constitution, the first electronic component is thermally connected to the heat dissipation member via the third heat transfer member 92C. As a result, the heat transfer path from the first electronic component to the heat dissipation member is newly provided via the third heat transfer member 92C. Therefore, cooling of the first electronic component is promoted, and the thermal characteristics of the electrical connection unit 100 are improved.

In the present embodiment, the first electronic component is fixed to the heat dissipation member. According to such a constitution, the first electronic component is physically connected to the heat dissipation member located on the +Z direction side. The heat generated in the first electronic component is easily transferred to the heat dissipation member via the attachment portion 14. Therefore, cooling of the first electronic component is promoted, and the thermal characteristics of the electrical connection unit 100 are improved.

In the present embodiment, the connection component 20 that forms the energization path from the first electronic component toward the first side, and the fourth heat transfer member 92D disposed between the connection component 20 and the heat dissipation member are further included. According to such a constitution, the connection component 20 that forms the energization path from the first electronic component is thermally connected to the heat dissipation member via the fourth heat transfer member 92D. As a result, the heat transfer path from the first electronic component to the heat dissipation member is newly provided via the connection component 20 and the fourth heat transfer member 92D. Therefore, cooling of the first electronic component is promoted, and the thermal characteristics of the electrical connection unit 100 are improved.

In the present embodiment, the electrical connection unit 100 further includes the first routing member (for example, the bus bar 42). The first routing member is disposed on a side (for example, the −Z direction side) opposite to the heat dissipation member with respect to the first electronic component and is electrically connected to the first electronic component. The first routing member is thermally connected to the external cooler CM by the first heat transfer member. According to such a constitution, the heat generated in the first electronic component or/and the first routing member is released to the external cooler CM via the first heat transfer member 92A. When the first routing member that forms the energization path together with the first electronic component is thermally connected to the external cooler CM via the first heat transfer member 92A, the thermal characteristics of the electrical connection unit 100 are improved.

In the present embodiment, the heat dissipation member is made of metal. According to such a constitution, heat is easily transferred to the heat dissipation member, and heat is less likely to be trapped in the electrical connection unit 100. Therefore, thermal characteristics of the electrical connection unit 100 can be improved.

In the present embodiment, the amount of heat generation of the first electronic component is greater than the amount of heat generation of the second electronic component. According to such a constitution, the first electronic component having a greater amount of heat generation than the second electronic component is easily thermally connected to the external cooler CM. As a result, temperature management for each of the electronic components (the first electronic component and the second electronic component) in the electrical connection unit 100 can be easily performed.

### <11. Modification Examples>

Next, several modification examples will be described. Note that a constitution other than that described below in each modification example is the same as the constitution of the above-described embodiment.

### First Modification Example

The routing board 40S is not limited to a structure in which the base member 41S and the bus bar 42 are integrated through insert molding. For example, the bus bar 42 may be disposed in the accommodation portion 55 after the base member 41S provided with the accommodation portion 55 that accommodates the bus bar 42 is molded. In this case, the bus bar 42 may be fixed to the accommodation portion 55 through fitting, or may be fixed to the accommodation portion 55 via an adhesive or other fixing means. In these cases, potting may be performed to fill a gap between the bus bar 42 and the accommodation portion 55.

### Second Modification Example

The base member of the routing board 40S is not limited to the base member 41S including the plate-shaped flat surface portion 51. The routing board 40S may be a base member (for example, an insulating sheet) having a sheet-shaped flat surface portion 51. In this case, the accommodation portion 55 may be formed by a part of the flat surface portion 51 following the outer shape of the bus bar 42. In the present disclosure, the “sheet-shaped” or “sheet” is not limited to a member having a thickness of 1 mm or more, and a member (so-called a film) having a thickness of less than 1 mm can also be used.

### Third Modification Example

The connection between the electronic component 10 and the bus bar 42 is not limited to connection using the connection component 20. The electronic component 10 may be directly connected to the bus bar 42 by using a fastening member (for example, a bolt or a screw), welding, or the like.

Several embodiments and modification examples have been described above. However, the embodiments and the modification examples are not limited to the examples described above. For example, the plurality of modification examples described above may be implemented in combination with each other.

### INDUSTRIAL APPLICABILITY

According to an embodiment, the thermal characteristics of the electrical connection unit can be improved.

### REFERENCE SIGNS LIST

100 Electrical connection unit
1A First structure
1B Second structure
10, 10S, 10T Electronic component
13, 13A, 13B Terminal
14 Attachment portion
14h Attachment hole (second attachment hole)
20 Connection component
40S Routing board
41S Base member
40T Cover member
42 Bus bar
46 First auxiliary member
47, 47A, 47B Connection bus bar
48 Second auxiliary member
51 Flat surface portion
51a First surface
51b Second surface
53 Opening portion
56 Locking portion
61 First connection portion
62 Second connection portion
63 Extending portion
70 Metal cover (heat dissipation member, metal member, and rigid member)
71 Peripheral wall
71h Holding portion
72 Ceiling wall portion
72a First surface
72b Second surface
72e1 First end
72e2 Second end
72e3 Third end
72e4 Fourth end
73 Fixing portion
73h Attachment hole (first attachment hole)
74 Holding portion
75 Insertion portion
81 Wall portion
82 Accommodation portion
83 Locking portion
91 Insulating sheet
92, 92A, 92B, 92C, 92D Heat transfer member
95 Fastening member
99 External connection bus bar
R Region
R1 First region (first space)
R2 Second region (second space)

What is claimed is:

1. An electrical connection unit comprising:
a heat dissipation member;
a first electronic component that is disposed on a first side of the heat dissipation member;
a first heat transfer member that is disposed on a first side of the first electronic component and is configured to be disposed between the first electronic component and an external cooler;
a second electronic component that is disposed on a second side of the heat dissipation member; and
a second heat transfer member that is disposed between the second electronic component and the heat dissipation member.

2. The electrical connection unit according to claim 1, further comprising:
a third heat transfer member disposed between the first electronic component and the heat dissipation member.

3. The electrical connection unit according to claim 1, wherein the first electronic component is fixed to the heat dissipation member.

4. The electrical connection unit according to claim 1, further comprising:
a connection component that forms an energization path from the first electronic component toward the first side; and
a fourth heat transfer member that is disposed between the connection component and the heat dissipation member.

5. The electrical connection unit according to claim 1, further comprising:
a first routing member that is disposed on a side opposite to the heat dissipation member with respect to the first electronic component and electrically connected to the first electronic component,
wherein the first routing member is configured to be thermally connected to the external cooler by the first heat transfer member.

6. The electrical connection unit according to claim 1, wherein the heat dissipation member is made of metal.

7. The electrical connection unit according to claim 1, wherein an amount of heat generation of the first electronic component is greater than an amount of heat generation of the second electronic component.
